(19) United States
(12) Patent Application Publication
(10) Pub. No.: US 2011/0039026 A1
(43) Pub. Date: Feb. 17, 2011

(54) FILM DEPOSITION APPARATUS, FILM DEPOSITION METHOD, AND COMPUTER READABLE STORAGE MEDIUM

(75) Inventors: Hitoshi Kato, Iwate (JP); Hiroyuki Kikuchi, Iwate (JP); Shigehiro Ushikubo, Iwate (JP)

Correspondence Address: IPUSA, P.L.L.C, 1054 31ST STREET, N.W., Suite 400, Washington, DC, 20007, US

(73) Assignee: TOKYO ELECTRON LIMITED

(21) Appl. No.: 12/852,545

(22) Filed: Aug. 9, 2010

(30) Foreign Application Priority Data
Aug. 11, 2009 (JP) 2009-186709

(51) Int. Cl. C23C 14/22; C23C 16/44

(52) U.S. Cl. 427/255.26; 118/730

(57) ABSTRACT

A silicon oxide film is deposited by rotating a rotation table on which a wafer W is placed to allow BTBAS gas to be adsorbed on an upper surface of the wafer W and supply a O₃ gas to the upper surface of the wafer W for allowing the BTBAS gas adsorbed on the upper surface of the wafer W to react. After depositing the silicon oxide film, a reforming process is performed every deposition cycle by supplying a plasma of Ar gas to the silicon oxide film on the wafer from an activated gas injector.

### CROSS-REFERENCE TO RELATED APPLICATION

This application claims the benefit of priority of Japanese Patent Application No. 2009-186709, filed on Aug. 11, 2009 with the Japanese Patent Office, the entire content of which is hereby incorporated by reference.

### BACKGROUND OF THE INVENTION

1. Field of the Invention

The present invention relates to a film deposition apparatus and a film deposition method for depositing a film on a substrate by carrying out plural cycles of supplying in turn at least two source gases to the substrate in order to form plural layers of a reaction product, and a storage medium storing a computer program for carrying out the film deposition method.

2. Description of the Related Art

As a film deposition technique in a semiconductor fabrication process, there has been known a process, in which a first reaction gas is adsorbed on a surface of a semiconductor wafer (referred to as a wafer hereinafter) and the like under vacuum and then a second reaction gas is adsorbed on the surface of the wafer in order to form one or more atomic or molecular layers through reaction of the first and the second reaction gases on the surface of the wafer, and such an alternating adsorption of the gases is repeated plural times, thereby depositing a film on the wafer. This technique is called Atomic Layer Deposition (ALD) or Molecular Layer Deposition (MLD) and advantageous in that the film thickness can be controlled at higher accuracy by the number of times of alternately supplying the reaction gases, and in that the deposited film can have excellent uniformity over the wafer. Therefore, this deposition method is thought to be promising as a film deposition technique that can address further miniaturization of semiconductor devices. This deposition technique can deposit a thin film at a temperature lower than that of a conventionally-used Chemical Vapor Deposition (CVD) technique. For example, a silicon oxide film (SiO₂ film) can be deposited at a deposition temperature no greater than 650° C.

There are known apparatuses described in, for example, Patent Documents 1-8 for performing a deposition method in numerous cycles in a short time. With these apparatuses, there are included a pedestal on which plural wafers are arranged in a circumferential direction (rotation direction) and plural gas supply portions for supplying process gas (reaction gas) to the wafers placed on the pedestal. The wafers placed on the pedestal are heated and rotated around a vertical axis relative to the pedestal and the gas supply portions. Further, by supplying the first and second reaction gases to the surface of the wafer from the plural gas supply portions and by providing partition walls between the gas supply portions that supply the reaction gases or by supplying an inert gas serving as a gas curtain, a process area where the first reaction gas is supplied and another process area where the second reaction gas is supplied can be separated.

As stated above, because the process areas are separated in order to impede the plural reaction gases from being intermixed with each other while the reaction gases are simultaneously supplied in a common vacuum chamber, the wafers are alternately exposed to the first reaction gas and the second reaction gas via the gas curtain or the partition wall. Therefore, because there is no need to replace the atmosphere inside the vacuum chamber whenever switching the type of reaction gas supplied inside the vacuum chamber, the reaction gases supplied to the wafer can be switched at high speed. Accordingly, a deposition process can be rapidly performed by the above-described methods.

When performing deposition of a thin film by using the ALD (MLD) method, impurities (e.g., organic substances and water vapor) contained in the reaction gas may be absorbed in the thin film due to low deposition temperature. In order to remove the impurities and form a consolidated thin film with few impurities, it is necessary to perform a subsequent process such as annealing the wafer at a temperature of several hundred ° C. or performing a plasma process on the wafer. However, performing such subsequent process on plural layers of thin films increases the number of steps and increases cost. Although there is a method of performing the subsequent process inside the vacuum chamber, it would be necessary to separate the process areas and the areas for performing the subsequent process so that the subsequent process does not adversely affect the processes performed in each process area. Therefore, although the area where the subsequent process is performed is rotated relative to each of the process areas and the pedestal, plasma may locally be generated when performing the plasma process as the subsequent process due to the relative rotation causing a disturbance of flow inside the vacuum chamber. This may prevent the subsequent process from being uniformly performed on the surface of the wafer. In such a case, the film thickness and the film property of the thin film may become inconsistent.

Patent Document 1: U.S. Pat. No. 7,153,542 (FIGS. 6(a), 6(b))

### Patent Document 2: Japanese Patent Application Laid-Open Publication No. 2001-254181 (FIGS. 1, 2)

Patent Document 3: Japanese Patent Publication No. 3,144,664 (FIGS. 1, 2, claim 1)
Patent Document 4: Japanese Patent Application Laid-Open Publication No. H4-287912
Patent Document 5: U.S. Pat. No. 6,634,314
Patent Document 6: Japanese Patent Application Laid-Open Publication No. 2007-247066 (paragraphs 0023 through 0025, 0058, FIGS. 12 and 20)

### Patent Document 7: United States Patent Publication No. 2007/218701

### Patent Document 8: United States Patent Publication No. 2007/218702

### SUMMARY OF THE INVENTION

The present invention has been made in view of the above, and provides a film deposition apparatus and a film deposition method for depositing a film on a substrate by carrying out plural cycles of supplying in turn at least two source gases to the substrate in order to form plural layers of a reaction product, which can provide a consolidated thin film with few impurities and having a uniform film thickness and film property, and a computer readable storage medium for causing the film deposition apparatus to execute the film deposition method.

A first aspect of the present invention provides a film deposition apparatus for placing a substrate on a substrate receiving area of a table inside a vacuum chamber, depositing a thin film on the substrate, supplying at least two types of reaction gases alternately to the substrate, and performing plural cycles of the supplying, thereby forming superposed layers of a reaction product, the film deposition apparatus including: a first reaction gas supplying part configured to supply a first reaction gas to the substrate; a second reaction gas supplying part configured to supply a second reaction gas to the substrate; an activated gas injector configured to perform a reforming process on the reaction product on the substrate by activating a process gas including a discharge gas and an addition gas having greater electron affinity than the discharge gas and generating plasma in a portion of the substrate receiving area between an inner edge toward a center of the table and an outer edge toward an outer circumference of the table; and a rotation mechanism configured to relatively rotate the first reaction gas supplying part, the second reaction gas supplying part, the activated gas injector, and the table with each other; wherein the first reaction gas supplying part, the second reaction gas supplying part, and the activated gas injector are arranged so that the substrate is positioned in this order during the relative rotation.

It is preferable that the activated gas injector includes a pair of parallel electrodes extending from the inner edge of the substrate receiving area to the outer edge of the substrate receiving area, and a gas supplying portion configured to supply the process gas between the parallel electrodes.

It is preferable that the activated gas injector includes a cover body covering the parallel electrodes and the gas supplying portion and having an opening at a bottom portion thereof, and a gas flow control part extending from lower sides of the cover body in a longitudinal direction and being outwardly bent in a flange-like shape.

It is preferable that the discharge gas includes a gas selected from an argon gas, a helium gas, an ammonia gas, a hydrogen gas, a neon gas, a krypton gas, a xenon gas, and a nitrogen gas, wherein the addition gas includes a gas selected from an oxygen gas, an ozone gas, a hydrogen gas, and an H₂O gas.

A second aspect of the present invention provides a film deposition method for placing a substrate on a substrate receiving area of a table inside a vacuum chamber, depositing a thin film on the substrate, supplying at least two types of reaction gases alternately to the substrate, and performing plural cycles of the supplying, thereby forming superposed layers of a reaction product, the film deposition method including the steps of: placing the substrate in the substrate receiving area on the table; supplying a first reaction gas to an upper surface of the substrate from a first reaction gas supplying part; supplying a second reaction gas to the upper surface of the substrate from a second reaction gas supplying part; and performing a reforming process on the reaction product on the substrate by activating a process gas including a discharge gas and an addition gas having greater electron affinity than the discharge gas and generating plasma in a portion of the substrate receiving area between an inner edge toward a center of the table and an outer edge toward an outer circumference of the table; wherein the supplying step of the first reaction gas, the supplying step of the second reaction gas, and the performing step of the reforming process are executed a plurality of times in this order by relatively rotating the first reaction gas supplying part, the second reaction gas supplying part, the activated gas injector, and the table with each other.

A third aspect of the present invention provides a computer-readable storage medium storing a computer program for use in a film deposition apparatus for placing a substrate on a substrate receiving area of a table inside a vacuum chamber, depositing a thin film on the substrate, supplying at least two types of reaction gases alternately to the substrate, and performing plural cycles of the supplying, to thereby form superposed layers of a reaction product, the computer program including: instruction steps for causing the film deposition apparatus to execute the above-described film deposition method.

### BRIEF DESCRIPTION OF THE DRAWINGS

FIG. 1 is a vertical cross-sectional view of a film deposition apparatus according to an embodiment of the present invention taken along line I-I′ of FIG. 3;

FIG. 2 is a perspective view illustrating an inner configuration of the film deposition apparatus of FIG. 1;

FIG. 3 is a horizontal cross-sectional view of the film deposition apparatus of FIG. 1;

FIG. 4 is a perspective view illustrating a partial inner configuration of the film deposition apparatus of FIG. 1;

FIG. 5 is a vertical cross-sectional view illustrating a partial inner configuration of the film deposition apparatus of FIG. 1;

FIG. 6 is an explanatory view for illustrating a manner in which separation gas or purge gas flows according to an embodiment of the present invention;

FIG. 7 is a perspective view illustrating an example of an activated gas injector provided in the film deposition apparatus according to an embodiment of the present invention;

FIG. 8 is a vertical cross-sectional view illustrating the activated gas injector of FIG. 7;

FIG. 9 is a schematic diagram illustrating a gas flow at the periphery of the activated gas injector of FIG. 7;

FIG. 10 is a schematic view for describing a method of attaching a gas introduction nozzle of the activated gas injector of FIG. 7;

FIG. 11 is a schematic diagram for describing a gas flow of the film deposition apparatus of FIG. 1;

FIG. 12 is a schematic diagram illustrating a separation area of the film deposition apparatus of FIG. 1;

FIG. 13 is a vertical cross-sectional view of a film deposition apparatus according to another embodiment of the present invention;

FIG. 14 is a vertical cross-sectional view of a film deposition apparatus according to another embodiment of the present invention;

FIG. 15 is a plan view of the film deposition apparatus according to the other embodiment of the present invention;

FIG. 16 is a perspective view of the film deposition apparatus according to the other embodiment of the present invention;

FIG. 17 is a vertical cross-sectional view of the film deposition apparatus according to the other embodiment of the present invention;

FIG. 18 is a plan view illustrating an example of a substrate processing apparatus including a film deposition apparatus according to an embodiment of the present invention; and

FIGS. 19-23 are graphs illustrating characteristics obtained from an embodiment of the present invention.

### DETAILED DESCRIPTION OF THE PREFERRED EMBODIMENT

According to an embodiment of the present invention, in forming a thin film of superposed layers of a reaction product by placing a substrate on a substrate receiving area of a table inside a vacuum chamber, supplying at least two types of reaction gases alternately to the substrate, and performing plural cycles of the supplying and by relatively rotating the film deposition apparatus includes the table, a first reaction gas supplying part for enabling a first reaction gas to be adsorbed on an upper surface of the substrate, a second reaction gas supplying part for supplying a second reaction gas that generates the reaction product by reacting to the first reaction gas adsorbed on the upper surface of the substrate, and an activated gas injector configured to perform a reforming process on the reaction product on the substrate by activating a process gas including a discharge gas and an addition gas having greater electron affinity than the discharge gas and generating plasma in a portion of the substrate receiving area between an inner edge toward a center of the table and an outer edge toward an outer circumference of the table, adsorbing of the first reaction gas, so that the adsorption of the first reaction gas, the generation of the reaction product, and the reforming process of the reaction product is performed plural times in this order. Accordingly, because plasma can be prevented from being locally generated by the addition gas and the reforming process can be uniformly performed on the substrate in the in-plane direction, there can be obtained a thin film having a sufficient density and a uniform film thickness and film property in the in-plane direction with few impurities.

Non-limiting, exemplary embodiments of the present invention will now be described with reference to the accompanying drawings. In the drawings, the same or corresponding reference symbols are given to the same or corresponding members or components.

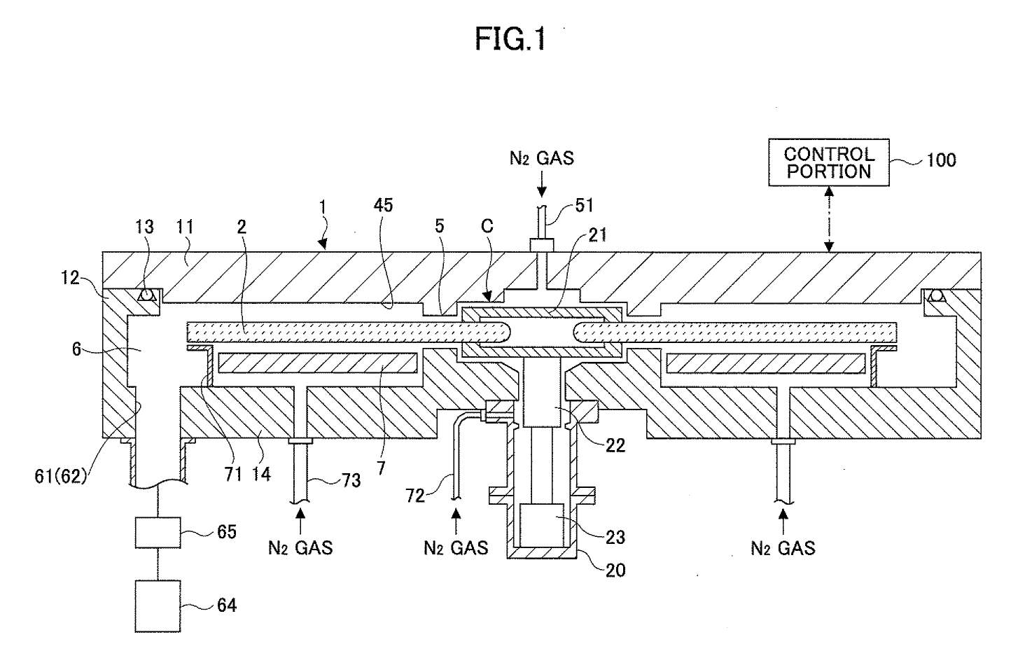

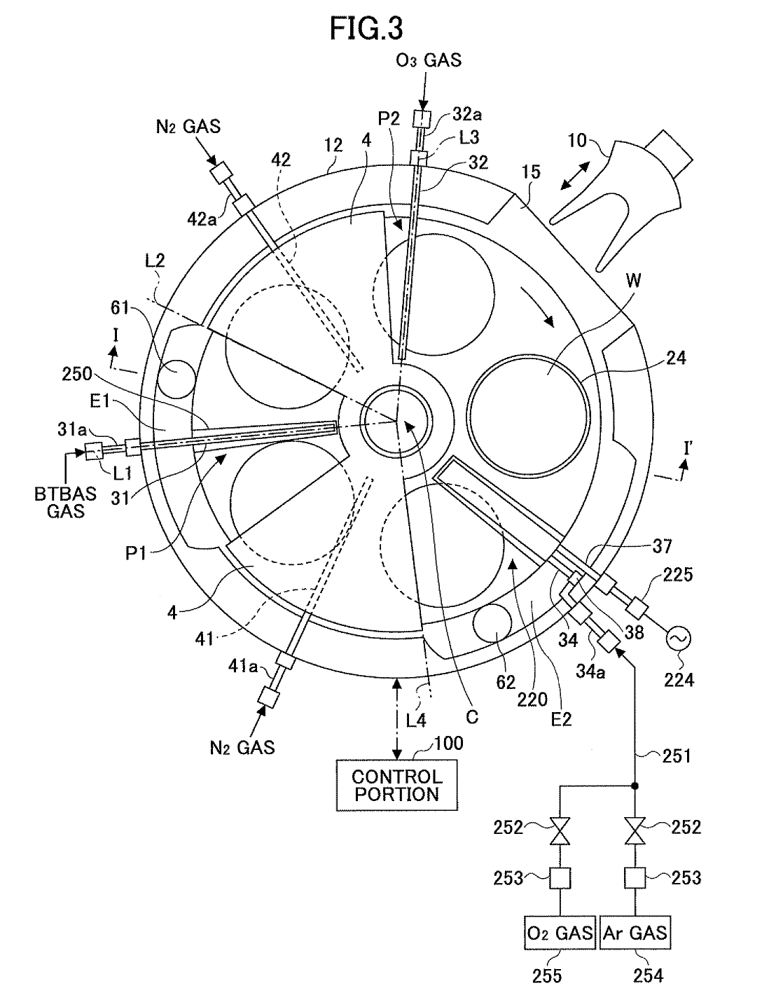

As illustrated in FIG. 1 (cross-sectional view taken along line I-I′ of FIG. 3), a film deposition apparatus according to an embodiment of the present invention has a vacuum chamber 1 having a flattened cylinder top view shape, and a turntable 2 (formed of, for example, carbon) that is located inside the vacuum chamber 1 and has a rotation center in a center of the vacuum chamber 1. The vacuum chamber 1 has a chamber body 12 from which a ceiling plate 11 can be separated. The ceiling plate 11 is hermetically attached on the chamber body 12 by reduced pressure therein via a sealing member such as an O-ring 13 provided on an upper opening of the chamber body 12. The ceiling plate 11 can be moved upward by a driving mechanism (not shown) when separating from the chamber body 12.

The turntable 2 is rotatably attached at its center onto a cylindrically shaped core portion 21. The core portion 21 is fixed on a top end of a rotational shaft 22 that extends in a vertical direction. The rotational shaft 22 penetrates a bottom portion 14 of the chamber body 12 and is fixed at the lower end to a driving mechanism 23 that can rotate the rotational shaft 22 clockwise in this embodiment. The rotational shaft 22 and the driving mechanism 23 are housed in a case body 20 having a cylinder with a bottom. The case body 20 is hermetically fixed to a bottom surface of the bottom portion 14 via a flange portion, which isolates an inner environment of the case body 20 from an outer environment.

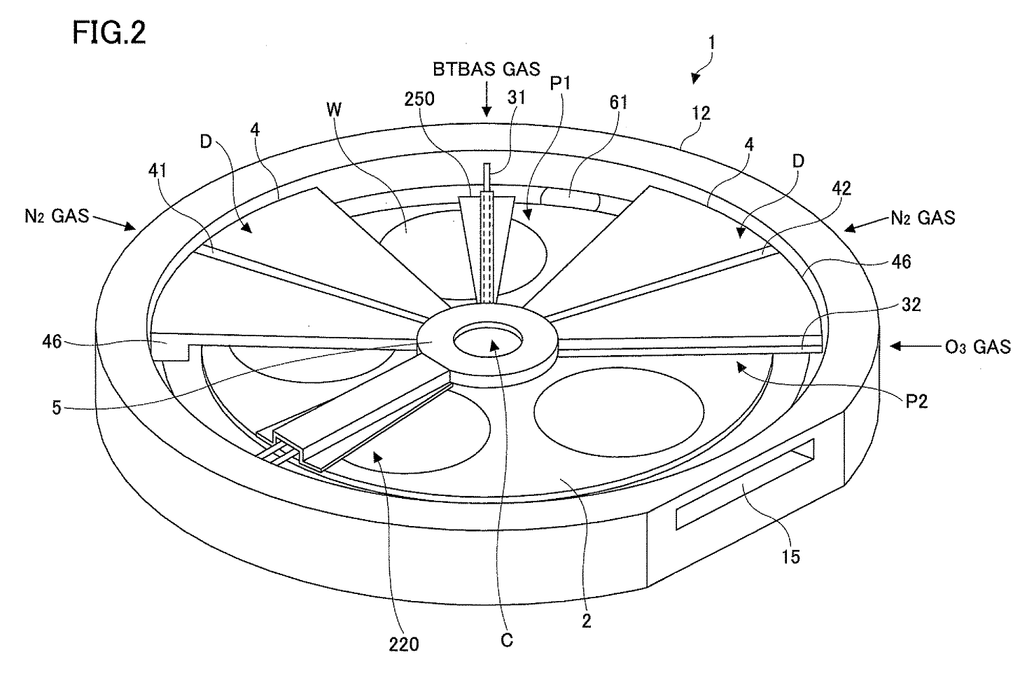

As shown in FIGS. 2 and 3, plural (e.g., five) circular concave portions 24, each of which receives a semiconductor wafer (referred to as wafer below), are formed in a top surface of the turntable 2 along a rotation direction (circumferential direction). Incidentally, only one wafer W placed at one of the concave portions is illustrated in FIG. 3, for the sake of convenience. The concave portion 24 has a diameter slightly larger, for example, by 4 mm than the diameter of the wafer W and a depth equal to a thickness of the wafer W. Therefore, when the wafer W is placed in the concave portion 24, a surface of the wafer W and a surface of the turntable 2 (area where the wafer W is not received) form substantially the same plane. If there is a relatively large step between the area of the turntable 2 and the wafer W, gas pressure is varied by the step, which may affect thickness uniformity across the wafer W. This is why the two surfaces are preferably at the same elevation, from a viewpoint of the thickness uniformity across the wafer. In the bottom of the concave portion 24, there are formed three through holes (not shown) through which three corresponding elevation pins 16 (described below) are raised/lowered. The elevation pins support a back surface of the wafer W and raise/lower the wafer W.

The concave portions 24 are wafer W receiving areas provided to position the wafers W and prevent the wafers W from being thrown outwardly by centrifugal force caused by rotation of the turntable 2.

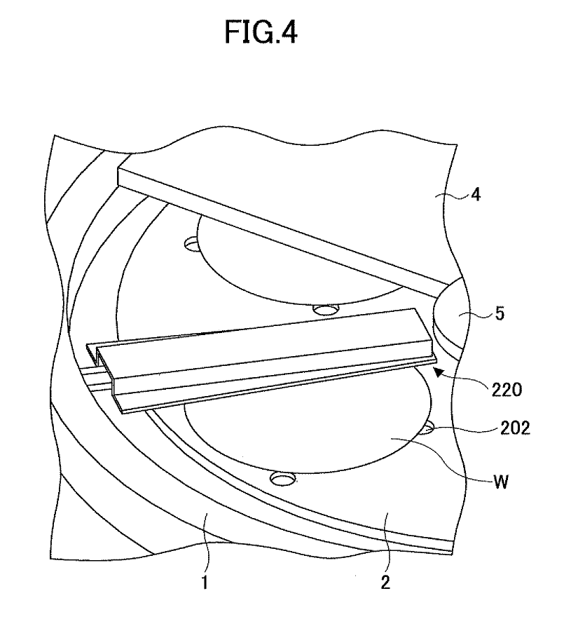

The concave portions 24 serve as substrate receiving areas provided to position the wafers W and prevent the wafers W from being thrown outwardly by centrifugal force caused by rotation of the turntable 2. However, substrate receiving areas (wafer W receiving areas) are not limited to the concave portions 24, but may be realized by guide members that are located at predetermined angular intervals on the turntable 2 to hold the circumference edge of the wafers W. In addition, the wafer W receiving areas may be realized by a chuck mechanism such as an electrostatic chuck. When the chuck mechanism is employed, an area where the wafer W is chucked serves as the substrate receiving area. Although omitted in FIGS. 2 and 3, plural recesses 202 may be formed at a periphery of the concave portion 24 in correspondence with each concave portion 24 for usage in placing the wafers W on the concave portions 24 or extracting the wafers W from the concave portions 24 as illustrated in FIG. 4.

As shown in FIGS. 2 and 3, first and second reaction gas nozzles 31, 32 (formed of, for example, quartz), two separation gas nozzles 41, 42, and an activated gas injector 220 are provided at angular intervals along the circumferential direction of the vacuum chamber 1 (rotation direction of the turntable 2) at positions facing the passing areas of the concave portions 24 of the turntable 24. In the illustrated example, the activated gas injector 220, the separation gas nozzle 41, the first reaction gas nozzle 31, the separation gas nozzle 42, and the second reaction gas nozzle 32 are arranged in this order along a clockwise direction from a transfer opening 15 (described below). The activated gas injector 220 and the nozzles 31, 32, 41, 42 are attached in a manner horizontally extending in a direction from the circumferential wall of the vacuum chamber 1 to the rotation center of the turntable 2. The base ends of the nozzles 31, 32, 41, 42, which are gas inlet ports 31a, 32a, 41a, 42a, respectively, penetrate the circumferential wall of the vacuum chamber 1. First reaction gas nozzle 31, 32, the auxiliary gas nozzle 200, and the separation gas nozzles 41, 42 horizontally extend in a direction from the circumferential wall to the center of the vacuum chamber 1, and are supported by attaching their base ends, which are gas inlet ports 31a, 32a, 200, 41a, 42a, respectively, on the outer circumference of the wall portion so that the inlet ports penetrate the circumferential wall. Further, in this embodiment, a gas flow regulating member 250 having the same configuration as the below-described cover body 221 is provided in a manner covering both left and right sides and an upper side of the first reaction gas nozzle 31 along a longitudinal direction of the first reaction gas nozzle 31 for the purpose of preventing N₂ gas or the like from entering the vicinity of the first reaction gas nozzle 31 and for the purpose of extending the time in which the wafer W is exposed to gas (BTBAS gas) ejected from the first reaction gas nozzle 31. Details of the gas flow regulating member 250 are explained below together with the explanation of the cover body 221. The reaction gas nozzle 31 serves as a first reaction gas supplying portion, and the reaction gas nozzle 32 serves as a second reaction gas supplying portion. The separation gas nozzles 41, 42 serve as separation gas supplying portions.

Although the reaction gas nozzles 31, 32, the activated gas injector 220, and the separation gas nozzles 41, 42 are introduced into the vacuum chamber 1 from the circumferential wall of the vacuum chamber 1 in the illustrated example, these nozzles 31, 32, 41, 42 and the injector 220 may be introduced from a ring-shaped protrusion portion 5 (described below). In this case, an L-shaped conduit may be provided in order to be open on the outer circumferential surface of the protrusion portion 5 and on the outer top surface of the ceiling plate 11. With such an L-shaped conduit, the nozzle 31 (the reaction gas nozzle 32, the activated gas injector 220, the separation gas nozzles 41, 42) can be connected to one opening of the L-shaped conduit inside the vacuum chamber 1 and the gas inlet port 31a (32a, 41a, 42a) and the below-described gas inlet port 34a can be connected to the other opening of the L-shaped conduit outside the vacuum chamber 1.

The first reaction gas nozzle 31 is connected to a gas supplying source of BTBAS (bis (tertiary-butylamino) silane, SiH₂ (NH—C(CH₃)₃)₂)) gas, which is a first source gas, via a flow rate adjustment valve or the like (not illustrated). The second reaction gas nozzle 32 is connected to a gas supplying source of ozone (O₃) gas, which is a second source gas, via a flow rate adjustment valve or the like (not illustrated). The separation gas nozzles 41, 42 are connected to gas supplying sources of N₂ (nitrogen) gas (not illustrated), which serves as a separation gas.

A distance between the gas ejection holes 33 of the reaction gas nozzles 31, 32 and the wafer W is, for example, from about 1 through 4 mm, preferably about 2 mm. A distance between the gas ejection holes 40 of the separation gas nozzles 41, 42 is, for example, about 1 through 4 mm, preferably about 3 mm. An area below the first reaction gas nozzle 31 may be referred to as a first process area P1 in which the BTBAS gas is adsorbed on the wafer W, and an area below the second reaction gas nozzle 32 may be referred to as a second process area 22 in which the O₃ gas is adsorbed on the wafer W and the BTBAS gas is oxidized.

The separation gas nozzles 41, 42 are provided in order to provide separation areas D for separating the first process area 21 and the second process area P2. In each of the separation areas D, there is provided a convex portion 4 on the ceiling plate 11 projecting downward, as shown in FIGS. 2-4. The convex portion 4 has a top view shape of a sector whose apex lies at the rotation center of the turntable and whose arced periphery lies near and along the inner circumferential wall of the vacuum chamber 1. The separation gas nozzles 41, 42 are installed in a groove portion 43 which is formed at the center of the convex portion 4 in a circumferential direction in a manner extending in a radial direction. That is, a circumferential distance between the center axis of the separation gas nozzle 41 (42) and one edge of one side of the sector-shaped convex portion 4 (an upstream side of the convex portion 4 relative to the rotation direction of the turntable 2) is substantially equal to the other circumferential distance between the center axis of the separation gas nozzle 41 (42) and the other edge of the other side (a downstream side of the convex portion 4 relative to the rotation direction of the turntable 2) of the sector-shaped convex portion 4.

Although the groove portion 43 is formed in a manner bisecting the convex portion 4 in this embodiment, the groove portion 43 in another embodiment may be formed in a manner that the upstream side of the convex portion 4 relative to the rotation direction of the turntable 2 is wider than the downstream side of the convex portion 4 relative to the rotation direction of the turntable 2.

Accordingly, with the above configuration, there are flat low ceiling surfaces 44 (first ceiling surfaces) on both sides of the separation gas nozzles 41 42, and high ceiling surfaces 45 (second ceiling surfaces) outside of the corresponding low ceiling surfaces 44. The convex portion 4 provides a separation space, which is a thin space, between the convex portion 4 and the turntable 2 in order to impede the first and the second reaction gases from entering the thin space and from being mixed.

Namely, taking an example of the separation gas nozzle 41, the separation gas nozzle 41 may impede the O₃ gas from entering the separation space from the upstream side of the rotation direction of the turntable 2 and the BTBAS gas from entering the separation space from the downstream side of the rotation direction of the turntable 2. “The gas being impeded from entering” means that the N₂ gas serving as the separation gas ejected from the separation gas nozzle 41 spreads between the first ceiling surfaces 44 and the upper surface of the turntable 2 and flows out to a space below the second ceiling surfaces 45 (adjacent space), which are adjacent to the corresponding first ceiling surfaces 44 in the illustrated example, so that the gases cannot enter the separation space from the adjacent space. “The gas cannot enter the separation space” means not only that the gases are completely prevented from entering the space below the convex portion 4 from the adjacent spaces, but also that the gases cannot proceed farther toward the separation gas nozzle 41 and thus the O₃ gas cannot be intermixed with the BTBAS gas even when a fraction of the gas enters the separation space. Namely, as long as such effect is demonstrated, the separation area D is to separate the first process area P1 from the second process area P2. A degree of “thin” of the thin space may be determined so that the effect of “the gas cannot enter the separation space” is demonstrated by a pressure difference caused between the thin space (a space below the convex portion 4) and the adjacent areas (areas below the second ceiling surfaces 45), and the specific height of the thin space may be different depending on the area of the convex portion 4 (the lower ceiling surfaces 44). The gases adsorbed on the wafer W can pass through the separation area D. Therefore, the gases in “the gas being impeded from entering” mean the gases in a gaseous phase.

In this embodiment, a wafer W having a diameter of about 300 mm is used. In this case, the convex portion 4 may have a circumferential length (along the circle concentric to the turntable 2) of, for example, about 146 mm along an interfacial position with respect to the below-described protrusion portion 5 at a distance 140 mm from the rotation center of the turntable 2, and a circumferential length of, for example, about 502 mm along an arc corresponding to the widest portion of the receiving area of the wafer W (concave portion 24). In addition, a circumferential length from one side of the separation gas nozzle 41 (42) to one side wall of the convex portion and a circumferential length from the other side of the separation gas nozzle 41 (42) to the other side wall of the convex portion are about 246 mm, respectively.

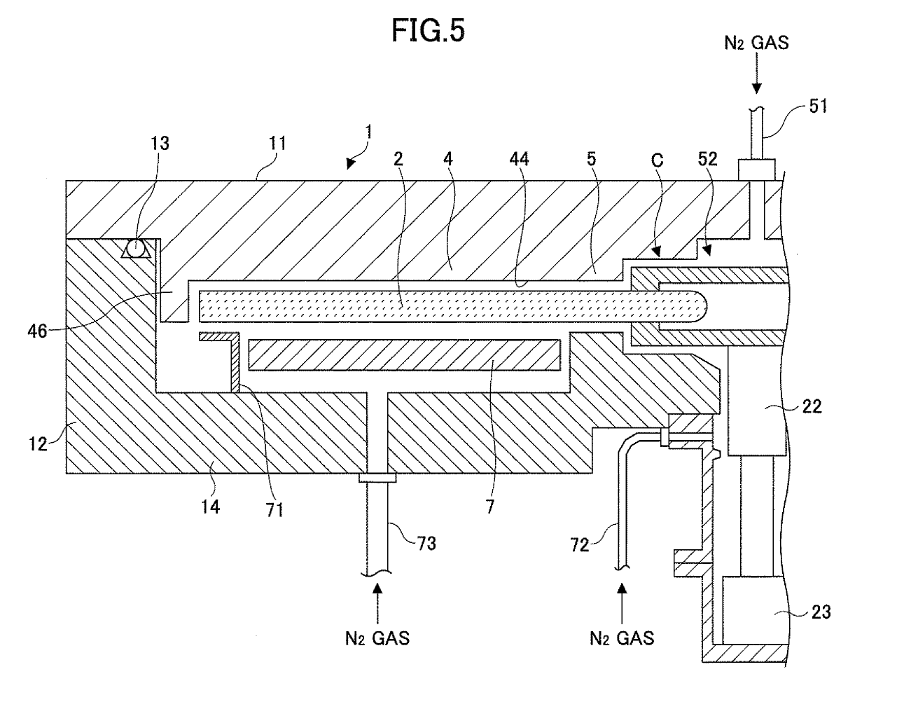

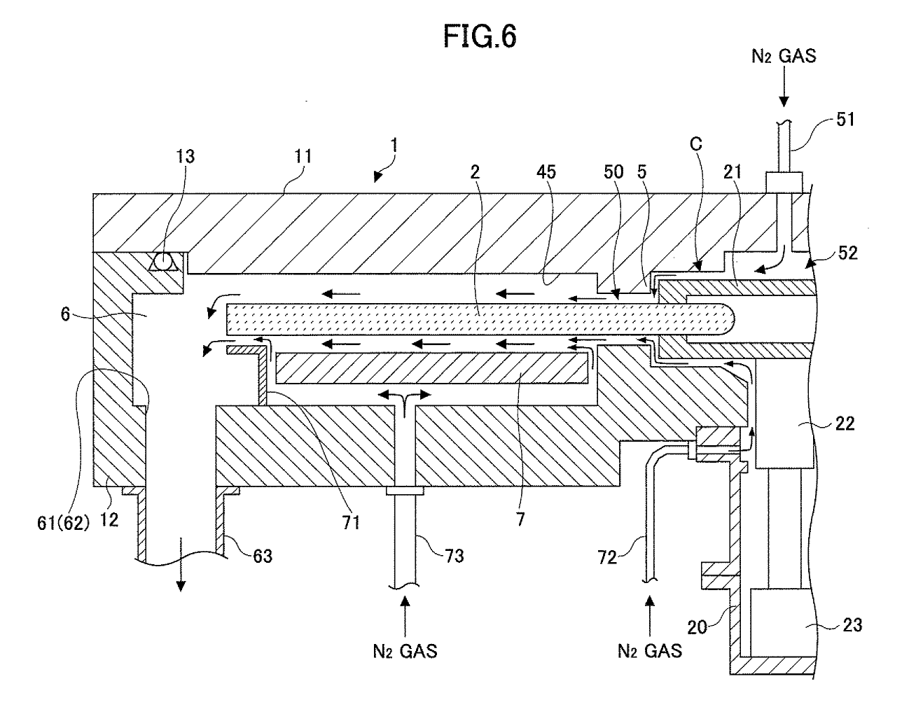

On the other hand, as illustrated in FIGS. 5 and 6, a protrusion portion 5 is provided on the lower surface of the ceiling plate 11 so that the inner circumference surface of the protrusion portion 5 faces the outer circumference surface of the core portion 21. The protrusion portion 5 opposes the turntable 2 in an outer area of the core portion 21. In addition, as illustrated in FIG. 5, the protrusion portion 5 is continuous with the rotation center part of the convex portion 4. The height of the lower surface of the protrusion portion 5 from the turntable 2 is the same as the height of the lower surface of the convex portion 4. FIGS. 2 and 3 are cross-sectional views where ceiling plate 11 is horizontally cut at a position lower than the ceiling surface 45 but higher than the separation nozzles 41, 42. The convex portion 4 is not limited to being formed integrally with the protrusion portion 5 and may be formed separately from the protrusion portion 5.

In this embodiment, although the convex portion 4 is formed by a single sector-shaped plate including the groove portion 43 and the groove portion has the separation gas nozzle 41 (42) provided therein, two sector-shaped plates may be fixed to a lower surface of the ceiling plate 11 with bolts on both sides of the separation gas nozzle 41 (42).

In this embodiment, the vacuum chamber 1 is provided with the first ceiling surfaces 44 and the second ceiling surfaces 45 higher than the first ceiling surfaces 44, which are alternately arranged in the circumferential direction. FIG. 5 shows a cross section of one portion of the vacuum chamber 1 where the higher ceiling surface 45 is formed. FIG. 5 shows a cross section of another portion of the vacuum chamber 1 where the lower first ceiling surface 44 is formed. As shown in FIGS. 2 and 5, the convex portion 4 has a bent portion 46 that bends in an L-shape at the outer circumferential edge of the convex portion 4 (portion of the outer edge of the vacuum chamber 1). Because the sector-shaped convex portion 4 is provided on the ceiling plate 11 and is detachable from the chamber body 12, there are slight gaps between the outer circumferential surface of the bent portion 46. The bent portion 46 is provided in order to impede the reaction gases from entering from both sides of the bent portion 46 and from being mixed with each other, in the same manner as the protrusion portion 5. The gaps between the bent portion 46 and the turntable 2 and between the bent portion 46 and the chamber body 12 may be the same as the height h of the first ceiling surface 44 from the turntable 2. In the illustrated example, an inner wall of the bent portion 46, the inner wall facing the outer circumferential surface of the turntable 2, serves as an inner circumferential wall of the vacuum chamber 1.

The inner circumferential wall of the chamber body 12 is close to the outer circumferential surface of the bent portion 46 and stands upright in the separation area D, as shown in FIG. 5. In order to have a rectangular shaped vertical cross-section, the inner circumferential wall of the chamber body 12 is dented outward from a height corresponding to the outer circumferential surface of the turntable 2 down through the bottom portion 14 of the chamber body 12 in areas other than the separation area D, as shown in FIG. 1. An area of this dented area connected to the first process area P1 is referred to as a first evacuation area E1. An area of this dented area connected to the second process area P2 is referred to as a second evacuation area E2. As illustrated in FIGS. 1 and 3, a first evacuation port 61 is provided in the bottom portion 14 below the evacuation area E1 and a second evacuation port 62 is provided in the bottom portion 14 below the evacuation area E2. The first and the second evacuation ports 61, 62 are connected to an evacuation unit 64 including, for example, a vacuum pump via corresponding evacuation pipes 63. In FIG. 1, reference numeral 65 indicates a pressure adjustment unit.

These evacuation ports 61, 62 are arranged on both sides of the separation area D, when being seen from above, in order to facilitate the separation effect demonstrated by the separation area D. Specifically, the first evacuation port 61 is arranged between the first process area 91 and the adjacent separation area D downstream of the rotation direction of the turntable 2 relative to the first process area 91, and the second evacuation port 62 is arranged between the second process area 92 and the adjacent separation area D downstream of the rotation direction of the turntable 2 relative to the second process area 92. The first evacuation port 61 is arranged between the first reaction gas nozzle 31 and a line extending from an first reaction gas nozzle side edge of the adjacent separation area D downstream relative to the first reaction gas nozzle 31 along the rotation direction of the turntable 2 in order to substantially exclusively evacuate the BTBAS gas. The evacuation port 62 is arranged between the second reaction gas nozzle 32 and a line extending from a second reaction gas nozzle side edge of the adjacent separation area D downstream relative to the second reaction gas nozzle 32 along the rotation direction of the turntable 2 in order to substantially exclusively evacuate the O₃ gas ejected from the second reaction gas nozzle 32. Namely, the first evacuation port 61 is provided between a straight line L1 shown by a chain line in FIG. 3 that passes through the center of the turntable 2 and the first process area 21 and a straight line L2 shown by a two-dot chain line in FIG. 3 that passes the center of the turntable 2 and the second process area P2. Additionally, the evacuation port 62 is provided between a straight line L3 shown by a chain line in FIG. 3 that passes through the center of the turntable 2 and the second process area P2 and a straight line L4 shown by a two-dot chain line in FIG. 3 that passes through the center of the turntable 2 and the upstream side edge of the separation area D situated adjacent to a downstream side of the second process area P2.

Although the two evacuation ports 61, 62 are provided in this embodiment, three evacuation ports may be provided by providing, for example, an additional evacuation port between the second reaction gas nozzle and the activated gas injector 220 in another embodiment. Moreover, an additional separation area D may be provided between the second reaction gas nozzle and the auxiliary gas nozzle 200 in order to separately evacuate the ethanol gas and the O₃ gas. Furthermore, four or more evacuation ports may be provided. In the illustrated embodiment, the first and second evacuation ports 61, 62 are configured to perform evacuation from the gaps between the inner circumferential wall of the vacuum chamber 1 and the circumferential edge of the turntable 2 by being positioned lower than the turntable 2. However, the first and second evacuation ports 61, 62 are not limited to being provided at the lower surface portion of the vacuum chamber 1 but may be provided at the side wall of the vacuum chamber 1. In the case of providing the first and second evacuation ports 61, 62 at the side wall of the vacuum chamber 1, the first and second evacuation ports 61, 62 may be provided higher than the turntable 2. Accordingly, because gas above the turntable 2 flows outward from the turntable 2, an advantageous effect of preventing scattering of particles compared to evacuating from a ceiling surface facing the turntable 2.

As shown in FIGS. 1, 5, and 6, a heater unit 7 as a heating portion is provided in a space between the bottom portion 14 of the vacuum chamber 1 and the turntable 2, so that the wafers W placed on the turntable 2 can be heated through the turntable 2 at a temperature of, for example, 300° C. determined by a process recipe. In addition, a cover member 71 is provided beneath the turntable 2 and near the outer circumference of the turntable 2 in order to surround the heater unit 7, so that the space where the heater unit 7 is located is partitioned from the outside area of the cover member 71. The cover member 71 has an upper edge bent outward to form a flange-like shape. The cover member 71 is arranged so that a slight gap is maintained between the back surface of the turntable 2 and the bent flange portion in order to prevent gas from flowing inside the cover member 71.

In an area closer to the center than the space where the heater unit 7 is housed, the bottom portion 14 comes close to the center back surface of the turntable 2 and the core portion 21, leaving slight gaps between the bottom portion 14 and the turntable 2 and between the bottom portion 14 and the core portion 21. In addition, there is a small gap between the rotational shaft 22 and an inner surface of the center hole of the bottom portion 14 through which the rotation shaft 22 passes. This small gap is in the gaseous communication with the case body 20. A purge gas supplying pipe 72 is connected to an upper portion of the case body 20 so that N₂ gas as a purge gas is supplied to the slight gaps, thereby purging the slight gaps. Moreover, plural purge gas supplying pipes 73 are connected at predetermined angular intervals to the bottom portion 14 of the chamber body 12 below the heater unit 7 in order to purge the space where the heater unit 7 is housed.

With such configurations, a space from the case body 20 through the heater unit housing space for housing the heater unit 7 is purged with N₂ gas from the purge gas supplying pipes 72, 73, and the purge gas is evacuated from the evacuation ports 61, 62 through the gap between the turntable 2 and the cover member 7, and the evacuation areas 6, as shown with arrows in FIG. 6. With this, the BTBAS gas or O₃ is impeded from entering from one of the first and second process areas P1, P2 to the other one of the first and second process areas P1, P2 through the space below the turntable 2. Therefore, the purge gas also serves as a separation gas.

A separation gas supplying pipe 51 is connected to the top center portion of the ceiling plate of the vacuum chamber 1, so that N₂ gas can be supplied as a separation gas to a space 52 between the ceiling plate 11 and the core portion 21. The separation gas supplied to the space 52 flows through the thin gap 50 between the protrusion portion 5 and the turntable 2 and then along the top surface of the turntable 2 toward the circumferential edge of the turntable 2. Because the space 52 and the gap 50 are filled with the N₂ gas, the reaction gases (BTBAS gas and O₃ gas) cannot be mixed through the center portion of the turntable 2. In other words, the film deposition apparatus according to this embodiment is provided with a center area C that is defined by the center portion of the turntable 2 and the ceiling plate 11 in order to separate the first process area P1 and the second process area P2 and is configured to have an ejection opening that ejects the separation gas toward the top surface of the turntable 2. The ejection opening corresponds to the gap 50 between the protrusion portion 5 and the turntable 2, in the illustrated example.

In addition, a transfer opening 15 is formed in a side wall of the vacuum chamber 1 as shown in FIGS. 2 and 3. Through the transfer opening 15, the wafer W is transferred into or out from the vacuum chamber 1 by an external transfer arm 10. The transfer opening 15 is provided with a gate valve (not shown) by which the transfer opening 15 is opened or closed. When the concave portion 24 of the turntable 2 is in alignment with the transfer opening 15 and the gate valve is opened, the wafer W is transferred into the vacuum chamber 1 and placed in the concave portion 24 as a wafer receiving portion of the turntable 2 from the transfer arm 10. In order to lower/raise the wafer W into/from the concave portion 24, there are provided elevation pins (not shown) that are raised or lowered through corresponding through-holes formed in the concave portion 24 of the turntable 2 by an elevation mechanism (not shown).

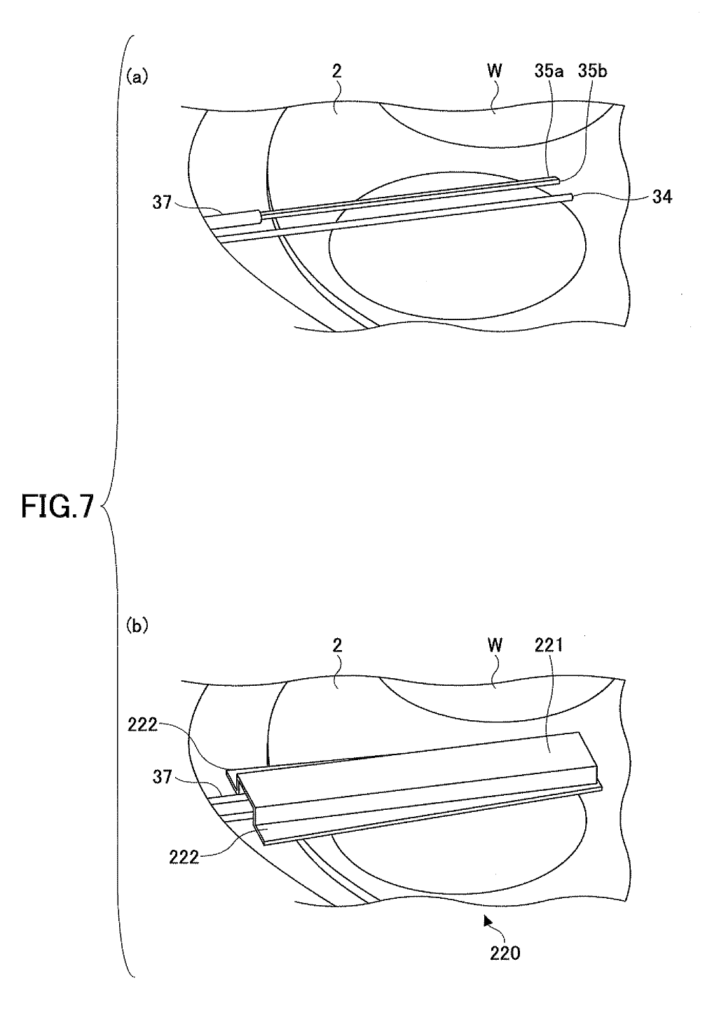

Next, the above-described activated gas injector 220 is described. The activated gas injector 220 is for reforming (performing property modification) a silicon oxide film (SiO₂ film) deposited on the wafer W by using plasma to cause a reaction between BTBAS gas and O3 gas. As illustrated in FIG. 7(a), the activated gas injector 220 includes a gas guidance nozzle 34 (serving as a gas supply portion made of, for example, quartz) for supplying process gas into the vacuum chamber 1 for generating plasma and a pair of parallel sheath pipes 35a, 35b made of quartz for generating plasma from the process gas supplied from the gas guidance nozzle 34. Reference numeral 37 indicates a protection pipe connected to the base end of the sheath pipes 35a, 35b.

The sheath pipes 35a, 35b are coated with, for example, a yttria (yttrium oxide, Y₂O₃) film having a thickness of about 100 μm. Yttrium oxide has an excellent resistance against plasma etching. The sheath pipes 35a, 35b have electrodes (not illustrated) made of, for example, a nickel alloy penetrating therethrough. High frequency power at a frequency of, for example, 13.56 MHz is applied at, for example, 500 W or less to the electrodes from a high frequency power source 224 via a matching box 225 as illustrated in FIG. 3. The electrodes extend in parallel and span between the center-side inner edge part and the outer-side outer edge part of the turntable 2 of the substrate receiving area of the wafer W, to thereby form parallel electrodes. It is to be noted that “substrate receiving area” is an area where the wafer W is received on the turntable 2 when a film is deposited on the wafer W. The sheath pipes 35a, 35b are arranged so that a gap between the electrodes 36a, 36b is about 10 mm or less, preferably about 4.0 mm. High frequency power at a frequency of 13.56 MHz is applied at, for example, 500 W or less to the electrodes 36a, 36b from a high frequency power source via a matching box (not shown). In the illustrated example, an inner space of the gas introduction nozzle 34 corresponds to the gas introduction passage; the cover body 221 corresponds to the passage defining member; and an area where the sheath pipes 35a, 35b are arranged and the process gas is activated corresponds to the gas activation passage. In addition, the circumferential wall of the gas introduction nozzle 34 corresponds to the partition wall that separates the gas introduction passage and the gas activation passage in other embodiments; and the gas holes 341 of the gas introduction nozzle 34 correspond to the through-holes allowing the gaseous communications between the gas introduction passage and the gas activation passage. Moreover, an area below the sheath pipes 35a, 35b corresponds to the ejection holes that eject the activated gas toward the wafer W.

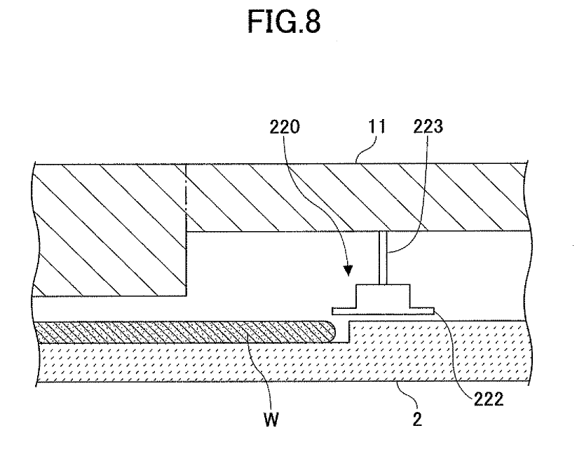

The cover body 221 is made of, for example, quartz and is for covering both sides (sides extending in the longitudinal direction) and an upper side of the area where the gas guidance nozzle 34 and the sheath pipes 35a, 35b are provided. The cover body 221 is fixed to the ceiling plate 11 of the vacuum chamber 1 by plural supporting members 223, as shown in FIG. 8. As shown in FIGS. 7(b) and 8, reference numeral 222 indicates an airflow control member (airflow control surface portion) 222 that horizontally extend in a longitudinal direction of the activated gas injector 220 from both lower sides of the cover body 221 to form a flange. In order to prevent O₃ gas and N₂ gas from entering the inside of the cover body 221, the airflow control surface portions 222 are formed in a manner that the gap between the lower edge surface of the airflow control surface portion 222 and the upper surface of the rotation table 2 is small and in a manner that the width u of the airflow control surface portion 222 becomes greater from the center portion side of the turntable to the outer circumferential side (side where gas flow becomes faster) of the turntable 2. It is to be noted that FIG. 7(a) illustrates a state where the cover body 221 is removed and FIG. 7(b) illustrates an external view where the cover body 221 is mounted.

A gap t between the airflow control surface portions 222 and the upper surface of the turntable 2 is, for example, 1 mm or less. In one example of the width u of the airflow control surface portion 222, the width u of the airflow control surface 222 may be 80 mm in a position facing the outer edge of the wafer W toward the rotation center of the turntable 2 and may be 130 mm in a position facing the outer edge of the wafer W toward the inner circumferential wall of the vacuum container 1. The space between the upper surface of the cover body 221 and the lower surface of the ceiling plate 11 of the vacuum container 1 (in the position where the gas guidance nozzle 34 and the sheath pipes 35a, 35b are installed) is set to be 20 mm or more (e.g., 30 mm) so that the space is greater than the gap t. As described above, the gas flow control member 250 having substantially the same configuration as the cover body 221 is also provided at the periphery of the first reaction gas nozzle 31.

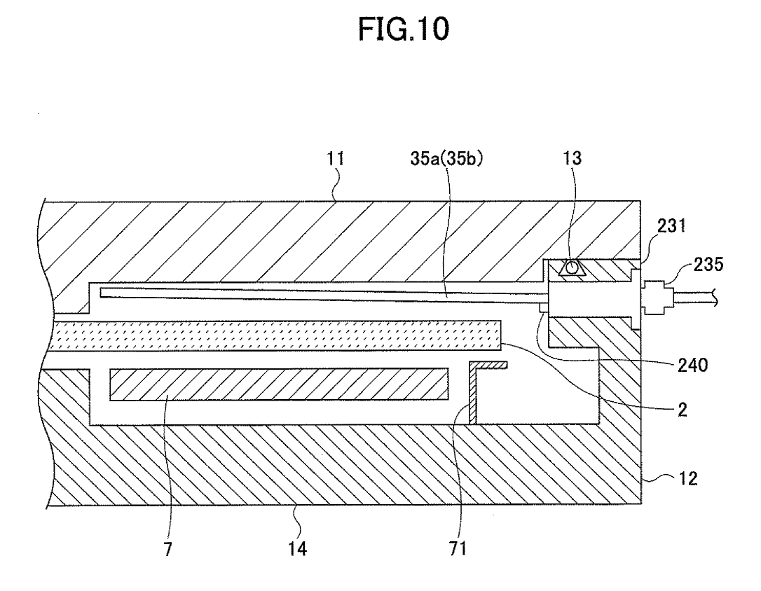

As illustrated in FIG. 10, an inclination adjustment mechanism 240 is provided inside the vacuum chamber 1 in such a manner that the inclination adjustment mechanism 240 supports a guard pipe 37 (sheath pipe 35a, 35b). The inclination adjustment mechanism 240 is a plate-like member formed, for example, along the inner circumferential wall of the vacuum chamber 1, and attached to the inner circumferential wall of the vacuum chamber 1 by an adjustment screw (e.g., a bolt) that can adjust an elevation of an upper surface of the inclination adjustment mechanism 240. With this, when the upper surface of the inclination adjustment mechanism 240 is vertically adjusted, the guard pipe 37 (sheath pipe 35a, 35b) may be inclined along the radial direction of the turntable 2 with respect to the turntable 2 because the guard pipe 37 is moved upward or downward by the inclination adjustment mechanism 240 while the base end (sidewall side of the vacuum container 1) of the guard pipe 37 is hermetically held by the O-rings 236. Accordingly, for example, the degree of reforming in the radial direction of the turntable 2 can be adjusted by the inclination adjustment mechanism 240. As illustrated in FIG. 10, the sheath pipe 35a, 35b may be inclined so that the distance between the wafer W and the sheath pipe 35a, 35b is shorter at the outer peripheral portion side (side where rotation speed of the turntable 2 is high) of the turntable 2 than the center side of the turntable 2.

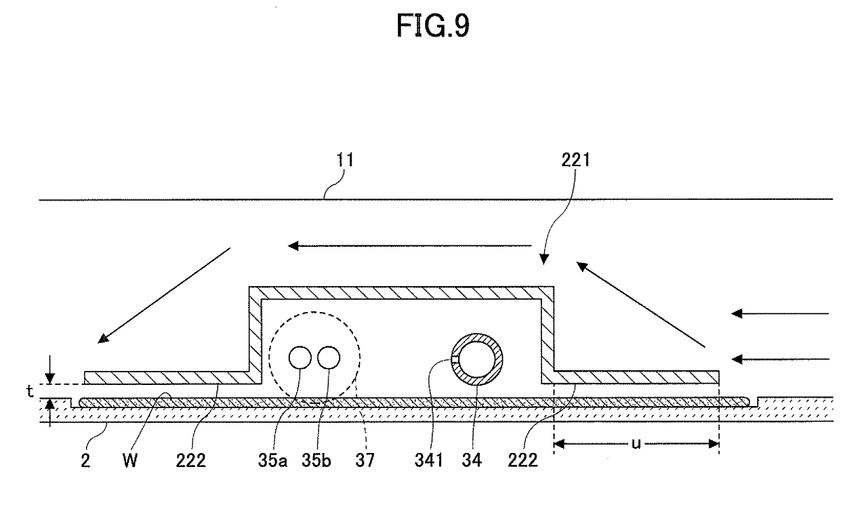

Returning to FIG. 3, one end of a plasma gas introduction path 251 for supplying process gas for generating plasma via the gas inlet port 34a at the outer side of the vacuum chamber 1 is connected to a base end of the gas introduction nozzle 34. The other end of the plasma gas introduction path 251 breaks into two branches where one is connected to a plasma generation gas source 254 at which plasma generation gas (discharge gas) is accumulated for generating plasma via a valve 252 and a flow rate adjustment portion 253 and the other is connected to an addition gas source 255 at which local discharge control gas (addition gas) is accumulated for controlling generation of plasma (chain) via the valve 252 and the flow rate adjustment portion 253. The plasma generation gas may be one or more types of gas including, for example, argon (Ar) gas, helium (He) gas, NH₃ gas, hydrogen (H₂) gas, neon (Ne) gas, krypton (Kr) gas, xenon (Xe) gas, nitrogen (N₂) gas, or a gas containing N. In this embodiment, Ar gas is used. The plasma control gas may be at least one type of gas having an electron affinity greater than that of the above-described plasma generation gas and having a property of being difficult to discharge. More specifically, the plasma control gas may be a gas including O₂ gas, or a gas containing an oxygen (O) element, a hydrogen (H) element, a fluorine (F) element, or a chlorine (Cl) element. In this embodiment, O₂ gas is used. In a case of performing a reforming process (property modification) on the wafer W, O₂ gas of approximately 0.5%-20% is added by weight Ar gas in order to prevent local (spot) generation of plasma (described below). In FIG. 9, reference numeral 341 indicates one or more gas ejection holes provided in the gas introduction nozzle 34 along the longitudinal direction of the gas introduction nozzle 34 for allowing a process gas for generating plasma to be ejected from the gas introduction nozzle 34 to the sheath pipes 35a, 35b.

The reason for using Ar gas (as the process gas for generating plasma) together with O₂ gas is described below. As described above, the activated gas injector 220 is used for performing a reforming process on a silicon oxide film by using plasma in every deposition cycle. In a case of using the activated gas injector 220, the generation of plasma (discharge) may become locally disrupted in the longitudinal direction of the activated gas injector 220 due to the passing of time or the rotation of the turntable 2. For example, plasma density may become uneven in the longitudinal direction or plasma density in the longitudinal direction may partly change along with the passing of time. The disruption of plasma can be confirmed by visually observing the radiation state of plasma through a transparent cover body 221 made of quartz.

The disruption of plasma is regarded to occur due to concaves and convexes (e.g., the recesses 202 of the turntable 2 (see FIG. 4), the gap between the side surface of the concave portion 24 and the outer edge of the wafer W, or the bolts (not shown) used for fixing components inside the vacuum chamber 1) inside the vacuum container 1 disrupting the gas flow inside the vacuum container 1. Because the gap t between the flow control surface portion 222 of the cover body 221 and the turntable 2 is extremely narrow, plasma may be generated locally at the gap t. Particularly, inert gas such as Ar gas has a tendency of causing plasma to be generated locally (concentrate) at a narrow gap portion.

As described above, the matching box 225 is provided between the sheath pipes 35a, 35b and the high frequency power source 224 for generating plasma evenly (matching). In a case where the turntable 2 is rotating at high speed (e.g., several hundred rpm), it is difficult for the matching box 225 to achieve even generation of plasma since the matching box 225 is unable to follow the changes of plasma. Further, due to the short distance between the sheath pipes 35a, 35b and the wafer W, plasma may reach the wafer W before being evenly dispersed in a case where generation of plasma is disrupted. Thus, the wafer W may be strongly affected by the disruption of plasma. Accordingly, the degree of the reformation process may be inconsistent in the longitudinal direction of the activated gas injector 220 (radial direction of the turntable 2) and the rotation direction of the turntable 2. Accordingly, as described below, the film thickness and the film quality may be inconsistent in the in-plane direction of the wafer W.

Accordingly, in this embodiment, local discharge (plasma generation) by Ar gas is controlled by using O₂ gas having a property of controlling chain generation of plasma together with Ar gas having a property of easily generating plasma.

Returning to FIGS. 1 and 3, the film deposition apparatus according to this embodiment is provided with a control portion 100 in order to control operations of the deposition apparatus. The control portion 100 includes a memory (not illustrated) that stores a program for performing the below-described deposition process and the reforming process. The program includes a group of steps for executing an operation of the apparatus described later, and may be installed to the memory of the control portion 100 from a computer-readable storage medium 100a such as a hard disk, a compact disk, a magneto-optical disk, a memory card, a flexible disk, and the like.

Next, a process carried out in the film deposition apparatus according to this embodiment is explained. First, the gate valve (not shown) is opened. Then, the wafer W is transferred into the vacuum chamber 1 through the transfer opening 15 by the transfer arm 10 and transferred to the concave portion 24 of the turntable 2. This wafer transferring is carried out by raising/lowering the elevation pins (not illustrated) from the bottom side of the vacuum container 1 via the through holes of the concave portion 24 when the concave portion 24 stops in a position in alignment with the transfer opening 15. Such wafer transferring is carried out by intermittently rotating the turntable 2, and five wafers are placed in the corresponding concave portions 24. Next, the gate valve is closed and the vacuum chamber 1 is evacuated to a predetermined pressure by the vacuum pump 64. Then, N₂ gas (separation gas) is ejected from the separation gas nozzles 41, 42 at a predetermined flow rate. In addition, N₂ gas is ejected from the separation gas supplying pipe 51 and the purge gas supplying pipes 71, 72 at a predetermined flow rate. The wafers W are heated by the heater unit 7 at a temperature of, for example, 300° C. via the turntable 2 while rotating the turntable 2 in a clockwise direction and adjusting the inside of the vacuum chamber 1 to a predetermined processing pressure. After the temperature of the wafers W is confirmed to be the predetermined temperature by a temperature sensor (not shown), BTBAS gas is supplied from the reaction gas nozzle 31, O₃ gas is supplied from the reaction gas nozzle 32, Ar gas of 9.0 slm and O₃ gas of 20 slm are supplied from the gas introduction nozzle 34, and high frequency power at a frequency of 13.56 MHz is applied at 500 W between the sheath pipes 35a, 35b.

In this case, with the activated gas injector 220, Ar gas and O₃ are supplied from the gas inlet port 34a and the gas introduction nozzle 34, respectively, and further to the sheath pipes 35a, 35b from the gas ejection holes provided formed in the circumferential wall of the gas introduction nozzle 34. Although the process gas for generating plasma are made into plasma at the area between the sheath pipes 35a, 35b, the rotation of the turntable 2 may cause disturbance of flow inside the cover body 221. Plasma (discharge) between the sheath pipe 35a (35b) and the turntable 2 may be caused by difference in the distance between the sheath pipes 35a, 35b and the turntable 2 with respect to the longitudinal direction of the sheath pipes 35a, 35b or by the distance between the sheath pipes 35a, 35b and the turntable 2 being changed along with the passing of time or changed by the rotation of the turntable 2. Although plasma may be locally generated, a chain of Ar gas plasma generation can be prevented owing to O₃ gas mixed in the process gas for plasma generation. Thus, the status of plasma is stabilized. The stably generated plasma descends toward wafer W moving (rotating) together with the turntable 2 below the activated gas injector 220.

By the rotation of the turntable 2, BTBAS gas is adsorbed on a surface of the wafer W in the first process area P1 and then the adsorbed BTBAS gas is oxidized in the second process area, to form one or more molecular layers of silicon oxide films. Impurities such as water vapor (OH radical) or organic substances may be contained in the silicon oxide film due to, for example, residual radicals of BTBAS. Then, when the wafer W reaches the area below the activated gas injector 220, a reforming process is performed on the silicon oxide film with the above-described plasma. More specifically, for example, by bombarding Ar ions onto the surface of the wafer W, the above-described impurities are released from the silicon oxide film and chemical elements inside the silicon oxide film are rearranged, to thereby achieve consolidation (high densification) of the silicon oxide film. Accordingly, after the reforming process is performed on the silicon oxide film, the silicon oxide film becomes consolidated and attains high resistance against wet-etching as described below. Because the plasma is in a stable state as described above, the reforming process is uniformly performed throughout the surface of the wafer W. Accordingly, the film thickness (shrinkage amount) and the wet-etching rate of the silicon oxide film become uniform in the surface of the wafer W. Accordingly, by rotating the turntable 2, adsorption of BTBAS gas, oxidation of BTBAS gas, and reforming is performed every deposition cycle. Further, layers of the silicon oxide film can be sequentially formed. Further, the silicon oxide film can be consolidated and attain resistance against wet-etching. Further, thin silicon oxide films can be formed having film thickness and the above-described resistance evenly in the surface of the wafer W and in-between wafers.

Although the separation area D is formed between the activated gas injector 220 and the second reaction gas nozzle 32 in the vacuum container 1, O₃ gas and N₂ gas are guided from the upstream toward the activated gas injector 220. However, because the cover body 22 is formed covering the electrodes 36a, 36b and the gas introduction nozzle 34, the upper area of the cover body 221 is wider than the lower area of the cover body 221 (gap t between the air flow control surface portion 222 and the turntable 2). Thus, it is difficult for gas flowing from the upstream side to enter the lower side of the cover body 221. Further, the gas flowing toward the activated gas injector 220 is guided to the upstream side by the rotation of the turntable 2. Therefore, although the flow of the gas becomes faster the more toward the outer circumference of the turntable 2, the gas can be prevented from entering the inside of the cover body with respect to the length direction of the activated gas injector 220 because the width u of the flow control surface portion 222 a the outer circumference side of the turntable 2 is greater than that of the inner circumference side of the turntable 2. Therefore, the gas flowing from the upstream side to the activated gas injector 220 flows to the evacuation port of the downstream side via the upper area of the cover body 221 as described above with reference to FIG. 9. Therefore, because the O₃ gas and the N₂ gas are hardly affected by activation by high frequency, generation of, for example, Noₓ is controlled. Further, the wafer W is also hardly affected by these gases. It is to be noted the impurities discharged from the silicon oxide film by the reforming process are discharged together with Ar gas and N2 gas from the evacuation port 62 after forming the impurities into gases.

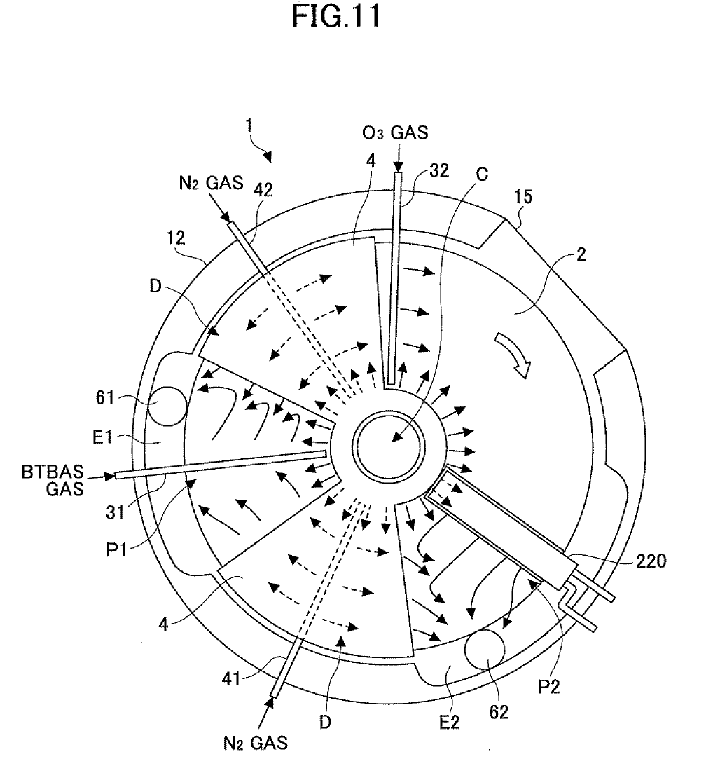

In this case, N₂ gas is supplied between the first process area P1 and the second process area P2. Further, N₂ gas (separation gas) is supplied to the center area C. Accordingly, BTBAS gas and O3 gas can be discharged without mixing with each other as illustrated in FIG. 11. Further, because the space between the bent portion 46 and the outer edge surface of the turntable in the separation area D is narrow as described above, the BTBAS gas and O3 gas do not mix even at the outerside of the turntable 2. Therefore, the atmosphere of the first process area and the atmosphere of the second process area P2 are substantially completely separated. Thus, BTBAS gas is discharged from the evacuation port 61 and O₃ gas is discharged from the evacuation port 62. As a result, BTBAS gas and O₃ gas do not mix in the atmosphere above the wafer W.

In this embodiment, the inner circumferential surface of the chamber body 12 is dented and is wide at the area below the ceiling surface 45 (at which the first reaction gas nozzle 31, the second reaction gas nozzle 32, and the activated gas injector 220 are arranged). Further, the first and second evacuation ports 61, 62 are positioned at the wide area. Accordingly, the pressure at the space below the ceiling surface 45 is lower than the pressure at the narrow space below the ceiling surface 33 and the center area C.

It is to be noted that because N₂ gas is purged to the lower side of the turntable 2, there is neither a risk for the gas guided into the evacuation area E to pass below the turntable 2 nor is there a risk of, for example, BTBAS gas or O₃ gas to flow into the gas supply area.

The parameters in this example are described as follows. In a case where the target substrate is a wafer W having a diameter of 300 mm, the rotation speed of the turntable 2 is, for example, 1 rpm-500 rpm. The process pressure is, for example, 1067 Pa (8 Torr). The wafer W is heated at temperature of, for example 350° C. The flow rate of the BTBAS gas is, for example, 100 sccm; the flow rate of the O₃ gas is, for example, 10000 sccm; the flow rate of the N₂ gas from the separation gas nozzles 41, 42 are, for example, 20000 sccm; and the flow rate of the N₂ gas from the separation gas supply pipe 51 at the center portion of the vacuum chamber 1 is, for example, 5000 sccm. Although the number of cycles of supplying reaction gas to a single wafer W (i.e. number of times the wafer W passes each of the process areas P1, P2) differs depending on the thickness desired, the number of cycles may be, for example, 1000 times.

With the above-described embodiment, in depositing a silicon oxide film by rotating the turntable 2 for enabling BTBAS gas to be adsorbed to the wafer W and then supplying O₃ gas to the surface of the wafer W for causing reaction of the BTBAS gas adsorbed on the surface of the wafer W, a reforming process is performed every cycle by supplying Ar gas plasma from the activated gas injector 220 to the silicon oxide film deposited on the wafer. Accordingly, a thin film having satisfactory density with few impurities and high resistance against wet etching can be obtained. A chain of Ar gas plasma generation is prevented by supplying O₂ gas together with Ar gas. Accordingly, plasma can be prevented from being generated locally with respect to the longitudinal direction of the activated gas injector 220 throughout the reforming process (deposition process). Accordingly, the reforming process can be uniformly performed on the surface of the wafer W and as well as in between the surfaces of the wafer W. Thus, even in a case where disruption of gas flow is caused in the area inside the cover body 221 by the rotation of the turntable 2, a case where plasma is locally generated in the longitudinal direction of the activated gas injector 220 by the distance between the sheath pipes 35a, 35b and the turntable 2 changing along with the elapse of time, or a case where the wafer W is susceptible to the inconsistency of plasma (local generation) due to the short distance between the plasma source (sheath pipes 35a, 35b) and the wafer W, uniform film property and film thickness can be attained at the surface of the wafer and between the surfaces of the wafer.

Further, in a case of depositing the silicon oxide film at a low deposition temperature no greater than 650° C., impurities are likely to remain in the film before performing the reforming process. Further, the amount of shrinkage caused by the reforming process is greater compared to a case of depositing at a high temperature. Accordingly, by preventing plasma from being locally generated, uniformity of film property and film thickness at the surface of the wafer W and between the surfaces of the wafer can be significantly improved. Further, because O₂ gas is used as the gas added to the Ar gas for plasma generation in a case of depositing the silicon oxide film, a bad effect such as impurities being absorbed in the film due to added gas or by-products being generated can be prevented.

Because members such as the cover body 221 (air flow control surface portion 222) can be positioned in the vicinity of the wafer W (turntable 2), the degree of freedom in designing the apparatus can be increased. In this case, the cover body 221 can prevent gas from the upstream side from entering the inside of the cover body 221. By preventing the influence of the gas, the reforming process can be performed in the middle of a deposition cycle. Accordingly, because there is no need to provide a dedicated separation area D between, for example, the second reaction gas nozzle 32 and the activated gas injector 220, the reforming process can be performed with reduced cost of the deposition apparatus. Further, the generation of by-products such as NOₓ can be prevented.

Because the sheath pipes 35a, 35b can be inclined when performing the reforming process on the silicon oxide film by using the activated gas injector 220, the distance with respect to the wafer W can be adjusted in the longitudinal direction of sheath pipes 35a, 35b. Accordingly, the degree of reforming can be matched with respect to, for example, the radial direction of the turntable 2.

Further, because the reforming process is performed every deposition cycle inside the vacuum chamber 1 and performed in a manner that the deposition process is not interfered in the middle of passing the wafer W through each of the process areas P1, P2, the reforming process can be performed at a shorter time compared to a case of, for example, performing the reforming process after completing a thin film deposition process.

Even with a high pressure range (pressure range of film deposition) which is not optimum for gas ionization, Ar gas can be activated (ionized) with a low output (to the extent necessary for the reforming process) because the distance between the electrode 36a and the electrode 36b is set to be short. It is to be noted that the rate of ionization becomes faster as the degree of vacuum in the vacuum chamber 1 increases whereas the adsorption efficiency of, for example, BTBAS gas decreases. Accordingly, the degree of vacuum inside the vacuum container 1 is to be set with consideration of deposition efficiency and reforming efficiency. Further, the value of high frequency electric power supplied to the electrodes 36a, 36b is to be appropriately set for accelerating the reforming process and not adversely affecting the deposition process.

Although the reforming process is performed whenever the deposition process is performed, the reforming process may be performed when the deposition process is performed plural number of times (e.g., 20 times). In this case, the supply of BTBAS gas, O₃ gas, and N₂ gas is stopped when performing the reforming process, and Ar gas from the gas introduction nozzle 34 is supplied to the activated gas injector 220 together with supplying high frequency to the sheath pipes 35a, 36. Then, the turntable 2 is rotated 200 times, for example, so that 5 wafers W sequentially pass the area below the activated gas injector 220. After completing the reforming process, the supplying of each of the gases is resumed for performing the deposition process. The reforming process and the deposition process are repeatedly performed sequentially. Even in this case, a thin dense film having low impurity concentration can be obtained. In this case, because the supply of O₃ gas and N₂ gas is stopped during the reforming process, the cover body 221 does not need to be provided as illustrated in FIG. 7 (a).

The deposition apparatus according to an embodiment of the present invention has plural wafers placed on the turntable 2 along the rotation direction of the turntable 2 and the wafers alternately pass through the first process area P1 and the second reaction area P2, thereby realizing the ALD (MLD) mode film deposition. Therefore, a high throughput film deposition is realized.

Furthermore, because the film deposition apparatus has the separation areas D including the low ceiling surface 44 between the first process area P1 and the second process area P2 and the separation gas is ejected from the center portion C defined by the rotation center of the turntable 2 and the vacuum chamber 1, and the reaction gases are evacuated, along with the separation gas spreading on both sides of the separation area D from the separation gas nozzle and the separation gas ejected from the center area C, through the gap between the circumferential edge of the turntable 2 and the inner circumferential wall of the chamber body 12, the reaction gases are impeded from being mixed with each other, thereby preferably realizing the film deposition. Moreover, because the reaction gases are not mixed, almost no deposits are made from the reaction gases on the turntable 2, thereby reducing particle problems. It is to be noted that the above-described embodiment can be applied to a case where a single wafer W is placed on the turntable 2. Further, in the case of supplying Ar gas together with O₂ gas according to the above-described embodiment, at least of part of the O₂ gas is made into plasma (activated) together with the Ar gas.

As for the process gas for depositing the silicon oxide film, the first reaction gas may be, for example, bis(tertiary-butylamino) silane (BTBAS), dichlorosilane (DCS), hexachlorodisilane (HCD), Trimethyl Aluminum (TMA), tris(dimethyl amino) silane (3DMAS), tetrakis-ethyl-methyl-amino-zirconium (TEMAZr), tetrakis-ethyl-methyl-amino-hafnium (TEMHf), bis(tetra methyl heptandionate) strontium (Sr(THD)₂), (methyl-pentadionate)(bis-tetra-methyl-heptandionate) titanium (Ti(MPD) (THD)), monoamine-silane, or the like. Further, ozone (O₃) and water vapor may be used as the second reaction gas that oxidizes the above-listed first reaction gases.

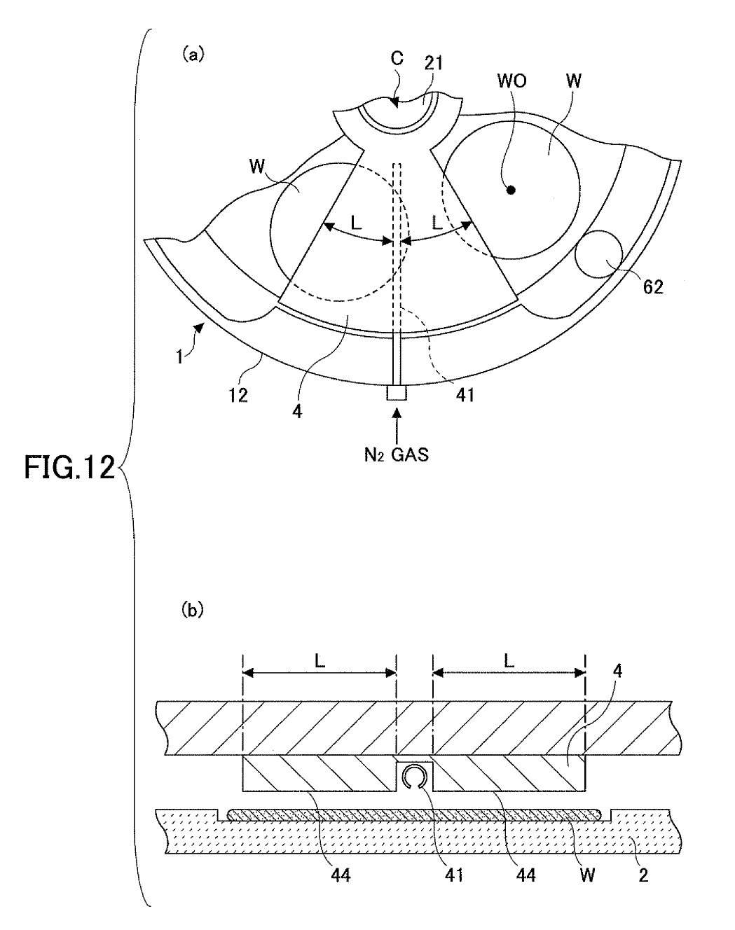

As shown in FIGS. 12(a) and 12(b), the ceiling surface 44 that creates the thin space in both sides of the separation gas nozzle 41 (42) may preferably have a length L of about 50 mm or more, which is measured along a route through which a wafer center WO passes due to the rotation of the turntable 2, when the wafer W to be processed has a diameter of 300 mm. When the length L is set to be small, the distance between the first ceiling surface 44 and the turntable 2 needs to be small accordingly in order to efficiently impede the reaction gases from entering the thin space below the ceiling surface 44 from both sides of the convex portion 4. In addition, because a circumferential speed of the turntable 2 becomes greater in a position farther away from the center of the turntable 2, the length L is required to be longer in the position farther away from the center of the turntable 2 in order to impede the reaction gases from entering the thin space below the ceiling surface 44. Taking account of the above, when the length L measured along the route through which the wafer center WO passes is smaller than 50 mm, the height h of the thin space needs to be significantly small. Therefore, measures to damp vibration of the turntable 2 are required in order to prevent the turntable 2 or the wafer W from hitting the ceiling surface 44 when the turntable 2 is rotated. In addition, when the rotational speed of the turntable 2 is higher, the reaction gas tends to enter the space below the convex portion 4 from the upstream side of the convex portion 4. Therefore, when the length L is smaller than 50 mm, the rotational speed of the turntable 2 needs to be reduced, which is inadvisable in terms of throughput. Therefore, the length L is preferably 50 mm or more, while the length L smaller than 50 mm can demonstrate the effect explained above depending on the situation. Specifically, the length L is preferably from about one-tenth of a diameter of the wafer W through about a diameter of the wafer W, more preferably, about one-sixth or more of the diameter of the wafer W along an arc that corresponds to a route through which a wafer center WO passes. The concave portion 24 is omitted in FIG. 12(a), for simplicity of illustration.

While the low ceiling surfaces (first ceiling surfaces) 44 are required on both sides of the separation gas nozzle 41 (42) in the embodiments according to the present invention as stated above, these ceiling surfaces may be provided on both sides of the reaction gas nozzles 31, 32 and the activated gas injector 32. In other words, the convex portion 4 may be extended substantially entirely to oppose the turntable 2 except for positions where the separation gas nozzles 41 (42), the reaction gas nozzles 31 (32), and the activated gas injector 220 are provided. Even in such a configuration, the same separation effect can be demonstrated. From another viewpoint, the first ceiling surface 44 located on both sides of the separation gas nozzle 41 (42) is extended to the reaction gas nozzle 31 (32), and the activated gas injector 220. In this case, the separation gas spreads on both sides of the separation gas nozzle 41 (42) and the reaction gas spreads on both sides of the reaction gas nozzles 31, 32, and the activated gas injector 220. Then, the separation gas and the reaction gas flow into each other below the convex portion 4 (in the thin space) and are evacuated through the evacuation port 61 (62).

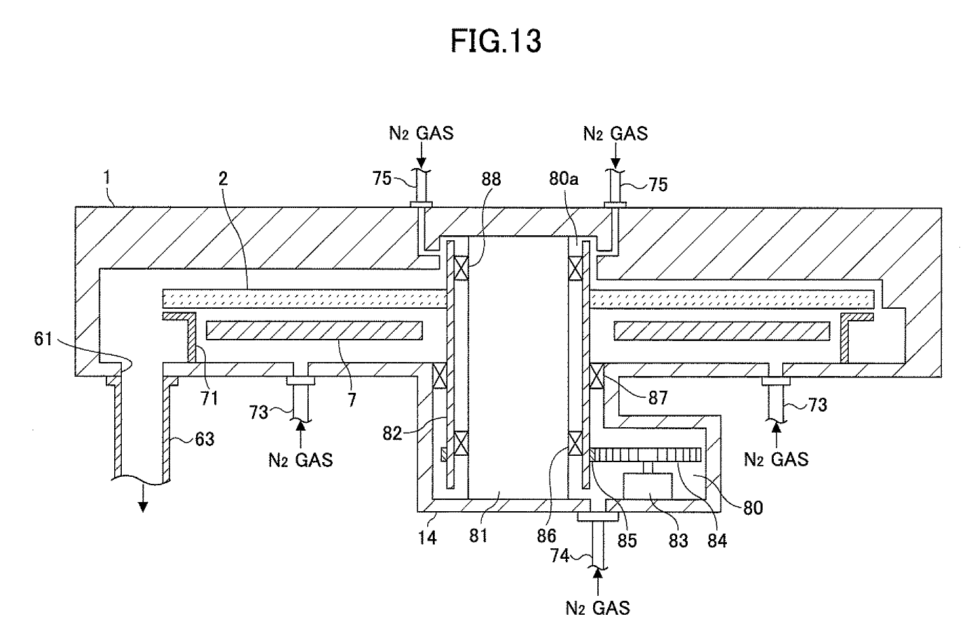

In the above embodiments, the rotational shaft 22 for the turntable 2 is located in the center of the vacuum chamber 1 and the space defined by the center portion of the turntable 2 and the ceiling plate 11 is purged with the separation gas. However, the film deposition apparatus according to another embodiment may be configured as shown in FIG. 13. In the film deposition apparatus of FIG. 13, the bottom portion 14 of the chamber body 12 is extended downward at the center and a housing space 80 is formed in the extended area. In addition, an upper inner surface (ceiling surface) of the vacuum chamber 1 is dented upward at the center and a concave portion 80a is formed in the dented area. Moreover, a pillar 81 is provided so that the pillar 81 extends from a bottom surface of the housing space 80 through an upper inner surface of the concave portion 80a. This configuration can prevent a gas mixture of the BTBAS gas from the first reaction gas nozzle 31 and the O₃ gas from the activated gas injector from flowing through the center area of the vacuum chamber 1.

In a mechanism for rotating the turntable 2, a rotation sleeve 82 is provided so that the rotation sleeve 82 coaxially surrounds the pillar 81. The turntable 2, which is a ring shape, is attached on the outer circumferential surface of the rotation sleeve 82. In addition, a motor 83 is provided in the housing space and a gear 84 is attached to a driving shaft extending from the motor 83. The gear 84 meshes with a gear 85 formed or attached on an outer circumferential surface of the rotation sleeve 82, and drives the rotation sleeve 82 via the gear 85 when the motor 83 is energized, thereby rotating the turntable 2. Reference numerals “86”, “87”, and “88” in FIG. 13 represent bearings. A gas purge supplying pipe 73 is connected to the bottom of the housing space 80, and purge gas supplying pipes 75 are connected to an upper portion of the vacuum chamber 1. The purge gas supplying pipes 75 supply purge gas to the space defined by an inner side wall of the concave portion 80a and the upper portion of the rotation sleeve 82. While two opening portions are shown in FIG. 13 for supplying purge gas to the space between the side surface of the concave portion 80a and the upper portion of the rotation sleeve 82, the number of the purge gas supplying ports (opening portions) and their arrangements may be determined so that the BTBAS gas and the O₃ gas are not mixed through an area near the rotation sleeve 82.

In the film deposition apparatus of FIG. 13, the space defined by an inner side wall of the concave portion 80a and the upper portion of the rotation sleeve corresponds to the separation gas ejection opening that ejects the separation gas toward the top surface of the turntable 2, when seen from the turntable 2. In addition, the center area C located in the center of the vacuum chamber 1 is defined by the ejection opening, the rotation sleeve 82 and the pillar 81.

The film deposition apparatuses are realized as a turntable-type film deposition apparatus in the above-described embodiments as shown in FIGS. 1, 2 and the like, the film deposition apparatus may be realized as a belt conveyer type, in other embodiments. Such a film deposition apparatus may have the wafer W placed on a belt conveyer rather than the turntable 2 and moved through the divided process areas and perform a deposition process using the reaction gas nozzles in the above-described embodiments. In addition, the film deposition apparatus may be realized as a single wafer type, in other embodiments. Such a film deposition apparatus may perform film deposition on a wafer placed on a fixed susceptor.

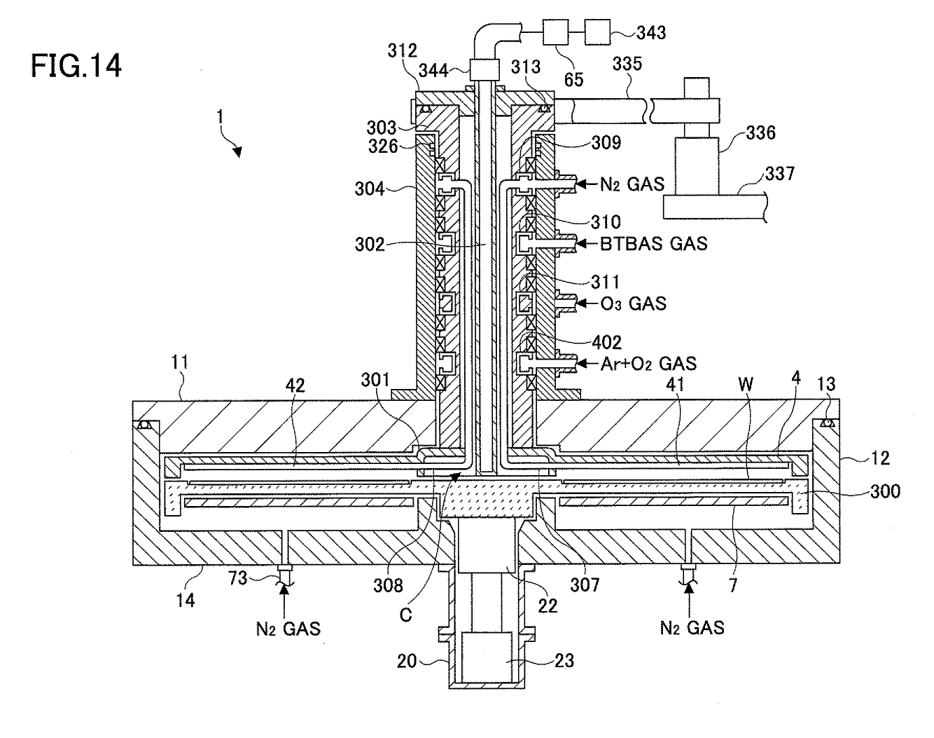

While the turntable 2 is rotated in relation to a gas supplying system (nozzles 31, 32, 41, 42, and activated gas injector 220) in the above embodiments, the gas supplying system may be rotated in relation to the stationary turntable 2. Namely, a film deposition apparatus according to an embodiment of the present invention may be configured so that the turntable 2 and the gas supplying system are rotated relative to each other. Such an embodiment is explained with reference to FIGS. 14 through 17. In the following explanation, the same or corresponding reference symbols are given to the same or corresponding members or components, and repetitive explanation is omitted.

A susceptor 300 is provided in the vacuum chamber 1, in the place of the turntable 2 explained in the above embodiments. A rotational shaft 22 is connected to a center of a lower surface of the susceptor 300 in order to rotate the susceptor 300 when the wafers W are placed on and removed from the susceptor 300. Plural (five in the illustrated example) of the above-described concave portions 24 are formed on the susceptor 300 along a circumferential direction of the susceptor 300.

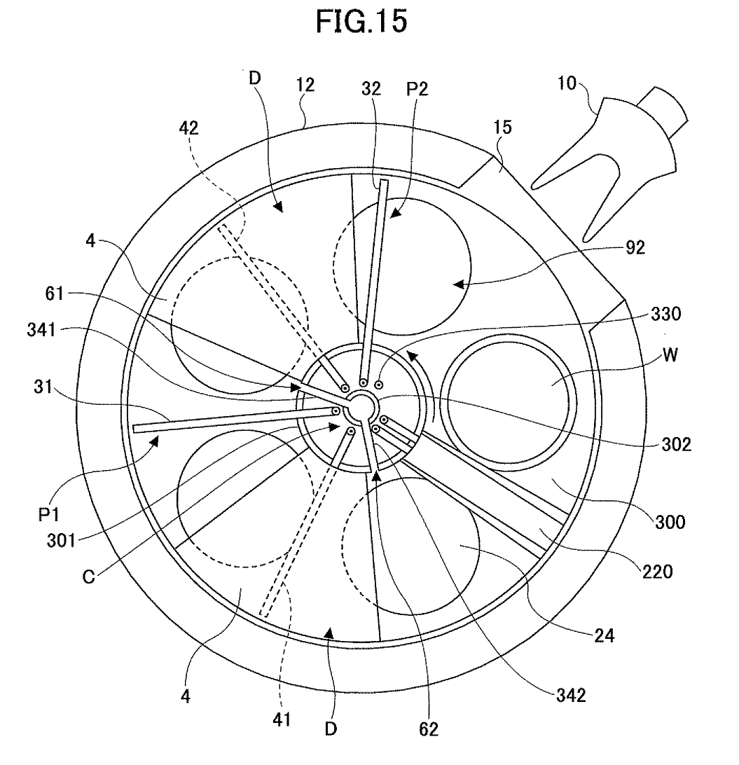

As shown in FIGS. 14 through 16, the nozzles 31, 32, 41, 42, and the activated gas injector 220 are attached to a flattened core portion 301 that has a disk shape and are provided above a center portion of the susceptor 300. Base end portions of the nozzles 31, 32, 41, 42 and the activated gas injector 220 penetrate a circumferential wall of the core portion 301. The core portion 301 is configured to be rotatable counterclockwise around a vertical axis, as described later. By rotating the core portion 301, the gas nozzles 31, 32, 41, 42 and the activated gas injector 220 are rotated above the susceptor 300. When the gas supplying system (nozzles 31, 32, 41, 42 and the activated gas injector 220) is rotated around a rotation center of the core portion 301, a direction along which the nozzles 31, 32, 41, 42 and the activated gas injector 220 come closer may be referred to as downstream, and a direction along which the nozzles 31, 32, 41, 42 and the activated gas injector 220 move far away may be referred to as upstream. In the same manner as the above-described film deposition apparatus illustrated in FIG. 1, this film deposition apparatus also has the nozzles 31, 32, 41, 42 and the activated gas injector 220 arranged so that BTBAS gas and O₃ gas can be supplied to each wafer W in this order and so that the wafers W having a silicon oxide film formed thereon by the BTBAS gas and the O₃ gas passes below the activated gas injector 220. FIG. 15 illustrates a state where the vacuum chamber 1 (the chamber body 12 and the ceiling plate 11) and a sleeve 304 (described later) fixed to the upper surface of the ceiling plate are removed.

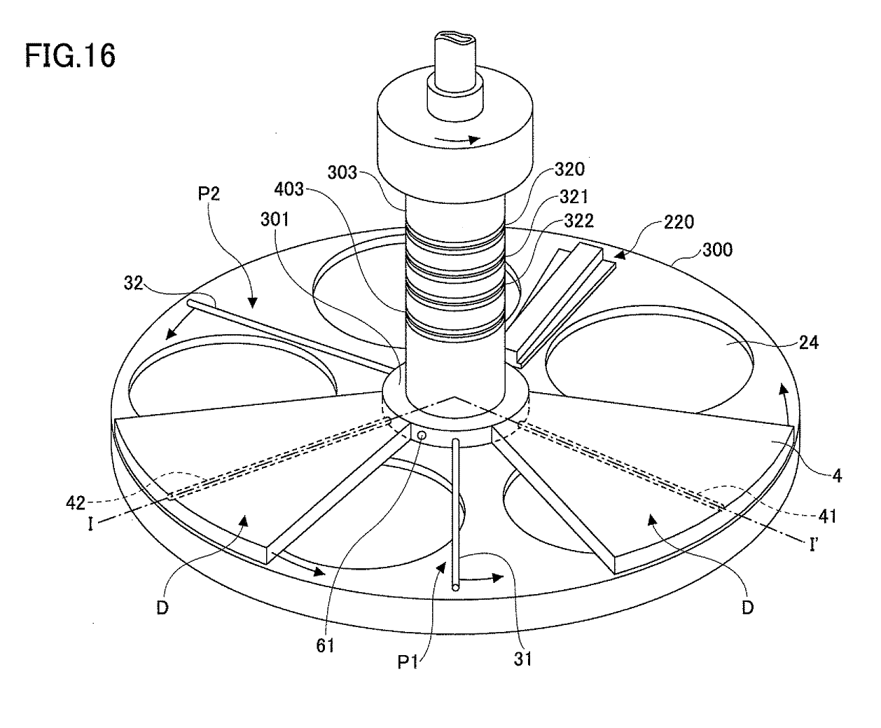

The convex portions 4 are attached to the circumferential surface of the core portion 301, and are configured to rotate above the susceptor 300 together with the gas nozzles 31, 32, 41, 42 and the activated gas injector 220. As shown in FIGS. 15 and 16, two evacuation ports 61, 62 are provided upstream of the rotation direction of the reaction gas supply nozzles 31, 32 and located in front of an engagement part between the convex portion 4 and the core portion 301. The evacuation ports 61, 62 are connected to a below-described evacuation pipe 302 so that the reaction gases and the separation gases are evacuated from the process areas P1, P2. In the same manner as the above-described embodiment, the evacuation ports 61, 62 are located on both sides of the separation portion D so that the evacuation port 61 evacuates substantially exclusively a corresponding reaction gas (BTBAS gas), and the evacuation port 62 evacuates substantially exclusively a corresponding reaction gas (O₃) gas.

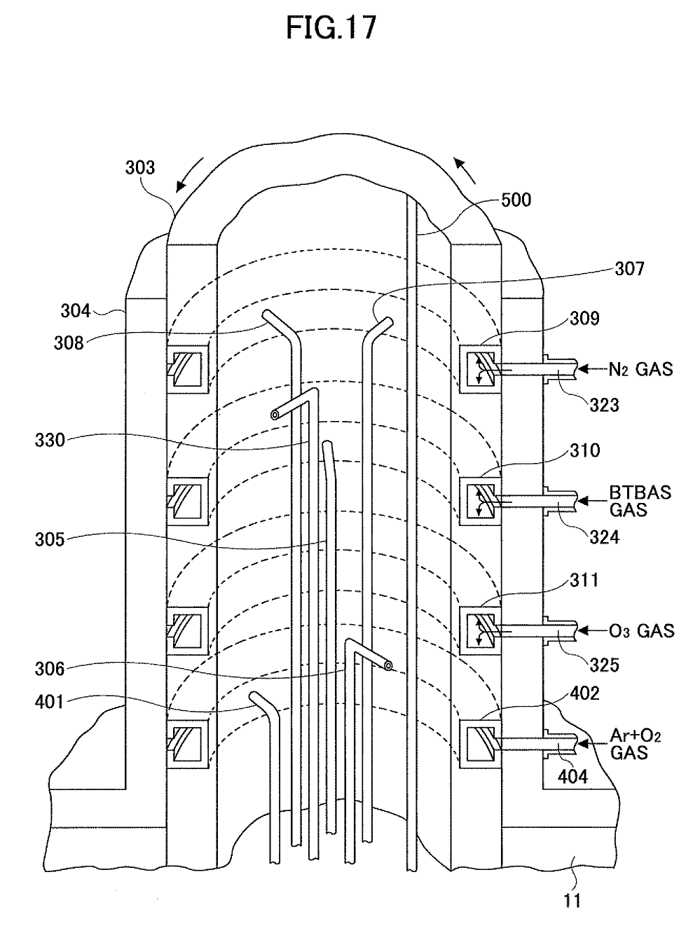

As shown in FIG. 14, a rotational cylinder 303 having a cylindrical shape is connected to a center portion of an upper surface of the core portion 301, and is rotatable around a vertical axis inside a sleeve 304 attached on the ceiling plate 11 of the vacuum chamber 1. When the rotational cylinder 303 is rotated, the core portion 301 is rotated by the rotational cylinder, and thus the nozzles 31, 32, 41, 42, the activated gas injector 220, and the convex portion 4 are rotated by the core portion 301. The cover body 221 of the activated gas injector 220 is fixed to the circumferential wall of the core portion 301 by the above-described supporting members 223. The core portion 301 provides an open space on the lower side thereof. The reaction gas nozzles 31, 32, 34 and the separation gas nozzles 41, 42 go through (penetrate) the circumferential wall of the core portion 301. In this open space, the reaction gas nozzle 31 (FIG. 15) is connected to a first reaction gas supplying pipe 305 (FIG. 17) for supplying the BTBAS gas; the reaction gas nozzle 32 (FIG. 15) is connected to a second reaction gas nozzle 306 (FIG. 17) for supplying O₃ gas; the reaction gas nozzle 34 (FIG. 15) is connected to a third reaction gas supplying pipe 401 for supplying a process gas for generating plasma (Ar gas and O₂ gas); the separation gas nozzles 41, 42 are connected to corresponding separation gas supplying pipes 307, 308 for supplying N₂ gas as the separation gas (for the sake of convenience, only the separation gas supplying pipes 307, 308 are illustrated in FIG. 14).

Similar to the separation gas supplying pipes 307, 308 illustrated in FIG. 14, the gas supplying pipes 305, 306, 401 are bent upward in an L shape near the rotation center of and in the open space of the core portion 301, penetrate through a ceiling portion of the core portion 301, and extend upward inside the rotational cylinder 303. The feeding wires 500 (FIG. 17) for feeding high frequency electric power from the high frequency power source 224 to the sheath pipes 35a, 35b are also formed penetrating through the ceiling portion of the core portion 301 and extending upward inside the rotational cylinder 303.

As illustrated in FIGS. 14 and 16, the rotational cylinder 303 has two cylinders that have different diameters and are stacked one above the other. The larger cylinder of the rotational cylinder 303 is rotatably supported by an upper end surface of the sleeve 304. With this, the rotational cylinder 303 is inserted into the sleeve 304 and is rotatable in a circumferential direction of the rotational cylinder 303 inside the sleeve 304, while the bottom end portion of the cylinder 303 penetrates through the ceiling plate 11 and is connected to the core portion 301. In FIG. 14, reference numeral 312 indicates a lid portion of the cylinder 303 and reference numeral 313 indicates an O-ring for closely coupling the lid portion 312 and the cylinder 303 together.

Referring to FIG. 17, in an outer circumferential surface of the cylinder 303, gas spreading conduits (ring-shaped conduits) are provided around the outer circumferential surface at predetermined vertical intervals. In the illustrated examples, a separation gas spreading conduit 309 for spreading the separation gas (N₂ gas), a first reaction gas spreading conduit 310 for spreading BTBAS gas, a second reaction gas spreading conduit 311 for spreading O₃ gas, and a third reaction gas spreading conduit 402 for supplying process gas for generating plasma are arranged in this order from the top to the bottom.

The gas spreading conduits 309 through 311, 402 have corresponding slits 320, 321, 322, 403 that are provided around the outer circumferential surface of the rotational cylinder 303 and open toward the inner circumferential surface of the sleeve 304. The corresponding gases are supplied to the gas spreading conduits 309 through 311, 402 by way of the corresponding slits 320, 321, 322, 403. In addition, gas supplying ports 323, 324, 325, 404 are provided at levels corresponding to the slits 320, 321, 322, 403 in the sleeve 304 that surrounds the rotational cylinder 303. The gases supplied from a gas supply source (not illustrated) to the gas supplying ports 323, 324, 325, 404 are supplied to the gas spreading conduits 309, 310, 311, 402 through the corresponding slits 320, 321, 322, 403 which are open toward the gas supplying ports 323, 324, 325, 404.

The rotational cylinder 303 inserted into the inside of the sleeve 304 has an outer diameter that is as close to an inner diameter of the sleeve 304 as possible, which makes it possible to close the slits 320, 321, 322, 403 with the inner circumferential surface of the sleeve 304, except for the gas supplying ports 323, 324, 325, 404. As a result, the gases supplied to the corresponding gas spreading conduits 309, 310, 311, 402 can spread only in the gas spreading conduits 309, 310, 311, 402, and do not leak into another gas spreading conduit, the vacuum chamber 1 or outside of the film deposition apparatus. In FIG. 14, reference numeral 326 represents a sealing member such as a magnetic sealing that prevents the gases from leaking out through a gap between the rotational cylinder 303 and the sleeve 304. Although not shown, the sealing members 326 are provided above and below each of the gas spreading conduits 309, 310, 311, 402, so that the gas spreading conduits 309, 310, 311, 402 are firmly sealed. In FIG. 17, the sealing member 326 is omitted.

Referring to FIG. 17, the gas supplying pipes 307, 308 are connected at the inner circumferential surface of the rotational cylinder 303 to the gas spreading conduit 309, and the reaction gas supplying pipes 305, 306 are connected at the inner circumferential surface of the rotational cylinder 303 to the corresponding gas spreading conduits 310, 311. In addition, the gas supplying pipe 401 is connected at the inner circumferential surface of the rotational cylinder 303 to the gas spreading conduit 402. With such configurations, the separation gas supplied from the gas supplying port 323 spreads in the gas spreading conduit 309, flows into the separation gas nozzles 41, 42 through the gas supplying pipes 307, 308, and is supplied to the vacuum chamber 1; and the reaction gases supplied from the corresponding gas supplying ports 324, 325 spread in the corresponding gas spreading conduits 310, 311, flow into the corresponding reaction gas nozzles 31, 32 through the corresponding gas supplying nozzles 305, 306, and is supplied to the vacuum chamber 1. Moreover, the process gas for generating plasma from the gas supplying port 404 is supplied to the vacuum chamber 1 via the gas spreading conduits 402 and the gas supplying pipe 401. The below-described evacuation pipe 302 is omitted in FIG. 17 for the sake of convenience.

As shown in FIG. 17, a purge gas supplying pipe 330 is connected to the separation gas spreading conduit 309, extends downward inside the rotational cylinder 303, and is open to the inner space (open space) of the core portion 301 as illustrated in FIG. 14, so that N₂ gas can be supplied into the inner space. As illustrated in FIG. 14, the core portion 301 is supported by the rotational cylinder 303 in a manner having a slight gap from the upper surface of the susceptor 300. Because the core portion 301 is not fixed to the susceptor 300, the core portion 301 can be freely rotated. However, if there is a gap between the susceptor 300 and the core portion 301, BTBAS gas or O₃ gas in one of the process areas 21, 22 may flow into the other of the process areas 21, 22 through the gap between the susceptor 300 and the core portion 301. However, in this embodiment, by forming the inner space of the core portion 301 (making the inside of the core portion 301 hollow) in a manner being open toward the susceptor 301, supplying the purge gas (N₂ gas) from the purge gas supplying pipe 330 to the inner space of the core portion 301, and enabling the purge gas to flow toward the process areas P1, P2 through the gap between the core portion 301 and the susceptor 300, the BTBAS (O₃) gas in one of the process areas P1, P2 can be substantially prevented from flowing into the other one of the process areas P2, P1 through the gap between the susceptor 300 and the core portion 301. Namely, the film deposition apparatus in this embodiment includes the center area C that is defined by the center portions of the susceptor 300 and the vacuum chamber 1, and has an ejection opening formed along the rotation direction of the core portion 301 in order to eject the purge gas along the upper surface of the susceptor 300. In this case, the purge gas serves as the separation gas to substantially prevent the BTBAS gas or O₃ gas in one of the process areas P1, P2 from flowing into the other one of the process areas P2, P1 through the gap between the susceptor 300 and the core portion 301. The gap between the core portion 301 and the susceptor 300 corresponds to the ejection opening.

Referring again to FIG. 14, a driving belt 335 is wound around an outer circumference of the cylinder having a larger diameter of the rotational cylinder 303. The driving belt 335 conveys rotational force from the driving portion 336 serving as a rotation mechanism arranged above the vacuum chamber 1 to the rotational cylinder 303, thereby rotating the rotational cylinder 303 inside the sleeve 304. In FIG. 14, reference numeral 337 indicates a supporting member that supports the driving portion 336 above the vacuum chamber 1.

In addition, the evacuation pipe 302 is arranged along the rotational center of the rotational cylinder 303 inside the rotational cylinder 303. A bottom end portion of the evacuation pipe 302 penetrates through the upper surface of the core portion 301 into the inner space of the core portion 301, and closes in the inner space. Suction pipes 341, 342 are connected at one end to a circumference of the evacuation pipe 302 extending inside the core portion 301, as shown in FIG. 16. In addition, the other ends of the suction pipes 341, 342 are open in the circumference of the core portion 301. With such configurations, the gas from the process areas P1, P2 can be evacuated by the evacuation pipe 302 through the suction pipes 341, 342 separately from the purge gas inside the core portion 301. While the evacuation pipe 302 is omitted in FIG. 17, as stated above, the gas supplying pipes 305, 306, 307, 308, 401 and the purge gas supplying pipe 330 are arranged around the evacuation pipe 302.

As shown in FIG. 14, an upper end portion of the evacuation pipe 302 penetrates through the lid portion 312 of the rotational cylinder 303 and is connected to, for example, a vacuum pump 343 serving as an evacuation portion. In FIG. 14, reference numeral 344 indicates a rotary joint that rotatably connects the evacuation pipe 302 to a pipe downstream of the evacuation pipe 302. Further, similar to the evacuation pipe 302 (although not illustrated in the drawings), the feeding wires 500 are configured to feed electricity from the high frequency power source 224 during rotation by using ring-shaped feeding paths formed in the periphery of the rotary joint 344.

Next, a film deposition method that may be carried out using the film deposition apparatus according to this embodiment is explained, focusing on differences from the previously explained film deposition methods (operations of the film deposition apparatuses). First, when the wafer W is transferred into the vacuum chamber 1, the susceptor 300 is intermittently rotated, so that five wafers W are placed in the corresponding concave portions 24 with cooperative operations of the transfer arm 10 and the elevation pins 16.

Then, the rotational cylinder 303 is rotated counterclockwise. At this time, while the gas spreading conduits 309-311, 402 provided in the rotational cylinder 303 (as illustrated in FIG. 17) are rotated accordingly, parts of the slits 320-322, 403 of the corresponding gas spread conduits 309-311, 402 are always open to corresponding openings of the gas supplying ports 323-325, 404. Therefore, the gases can be continuously supplied to the corresponding gas spreading conduits 309-311, 402.

The gases supplied to the gas spreading conduits 309 through 311, 402 are supplied to the corresponding process areas P1, P2, activated gas injector 220, and separation areas D from the corresponding reaction gas nozzles 31, 32, 34 and separation gas nozzles 41, 42 through the corresponding gas supplying pipes 305 through 308, 401 connected to the corresponding gas spreading conduits 309 through 311, 402. Because these gas supplying pipes 305 through 308, 401 are fixed on the rotational cylinder 303, and the reaction gas nozzles 31, 32, 34 and the separation gas nozzles 41, 42 are fixed on the rotational cylinder 303 via the core portion 301, the gas supplying pipes 305 through 308, 401 and the gas nozzles 31, 32, 41, 42 and the activated gas injector 220 are rotated along with the rotational cylinder 303 and supply the corresponding gases to the vacuum chamber 1. In addition, the sheath pipes 35a, 35b are also rotated along with the nozzles 31, 32, 41, 42, and the activated gas injector 220 and supplies the process gas for generating plasma (plasma generated between the sheath pipes 35a, 35b) to the silicon oxide film of the wafer W below the sheath pipes 35a, 35b.

At this time, the purge gas supplying pipe 330 rotating integrally with the rotational cylinder 303 supplies the N₂ gas serving as the separation gas, and thus the N₂ gas is ejected from the center area C, namely, the gap between the core portion 301 and the susceptor 300, along the upper surface of the susceptor 300. In addition, because the evacuation ports 61, 62 are formed in the circumference of the core portion 301 in order to open to the spaces below the second ceiling surfaces 45 where the reaction gas nozzles 31, 32 are arranged, pressures of the spaces below the second ceiling surfaces 45 are lower than the pressures of the thin spaces below the first ceiling surface 44 and the center area C. Therefore, the BTBAS gas and the O₃ gas are not intermixed and are independently evacuated from the vacuum chamber 1 in the same manner as the film deposition apparatuses in the previous embodiments.

In such a manner, the process areas P1, P2 and the activated gas injector 220 can pass above the wafers W stationed on the susceptor 300 can apparently pass through the process areas 91, 92, 90 in this order, so that adsorption of the BTBAS gas, oxidization due to the O₃ gas, and a reforming process are carried out in this order.

Also in this embodiment, the reforming process can be performed so that the film thickness and the film property is uniform with respect to the surface of the wafer W and in-between the surfaces of the wafer W. Namely, the same effects (advantages) can be provided by this embodiment.

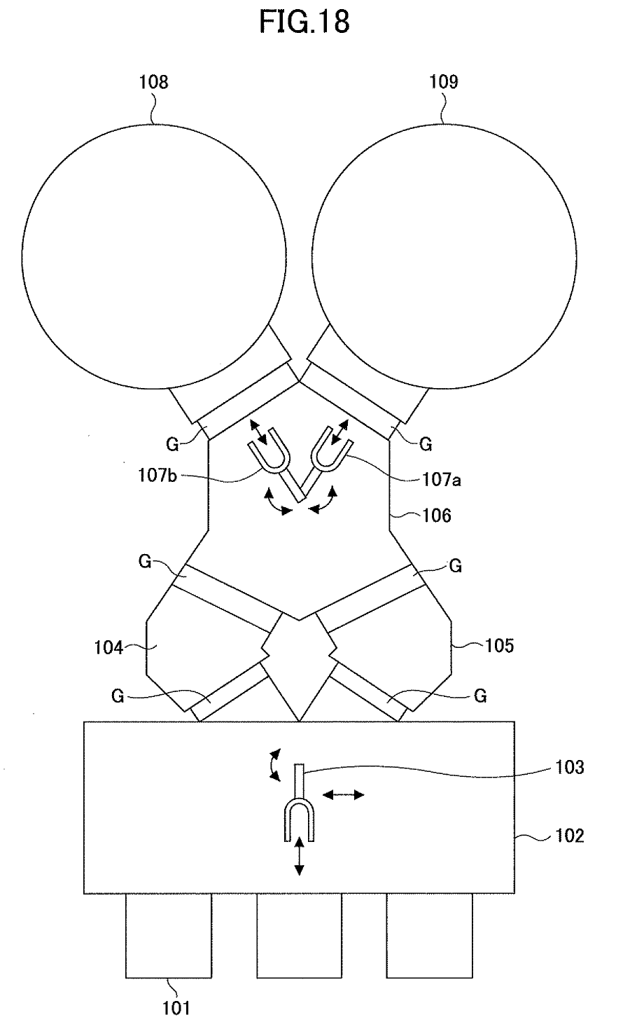

The film deposition apparatus according to embodiments of the present invention may be integrated into a wafer process apparatus, an example of which is schematically illustrated in FIG. 18. In FIG. 18, reference numeral “101” indicates a closed-type wafer transfer cassette such as a Front Opening Unified Pod (FOUP) that houses, for example, 25 wafers; reference numeral “102” indicates an atmospheric transfer chamber where a transfer arm 103 is arranged; reference numerals “104” and “105” indicate load lock chambers (preparation chambers) whose inner pressure is changeable between vacuum and an atmospheric pressure; reference numeral “106” indicates a vacuum transfer chamber where two transfer arms 107 are provided; and reference numerals “108” and “109” indicate film deposition apparatuses according to an embodiment of the present invention. The wafer transfer cassette 101 is brought into a transfer port including a stage (not shown); a cover of the wafer transfer cassette 101 is opened by an opening/closing mechanism (not shown); and the wafer is taken out from the wafer transfer cassette 101 by the transfer arm 103. Next, the wafer is transferred to the load lock vacuum chamber 104 (105). After the load lock vacuum chamber 104 (105) is evacuated to a predetermined reduced pressure, the wafer is transferred further to one of the film deposition apparatuses 108, 109 through the vacuum transfer vacuum chamber 106 by the transfer arm 107. In the film deposition apparatus 108 (109), a film is deposited on the wafer in such a manner as described above. Because the wafer process apparatus has two film deposition apparatuses 108, 109 that can house five wafers at a time, the ALD (or MLD) mode deposition can be performed at high throughput.

Although Ar gas and O₂ gas are supplied as a mixture from the gas introduction nozzle 34 according to the above-described embodiments, two separate nozzles may be provided in the cover body 22 so that Ar gas and gas can be separately supplied from each of the nozzles.

Although silicon oxide films are formed by using, for example, BTBAS gas and O₃ gas according to the above-described embodiments, a reforming process may be performed in a case of forming silicon nitride films using TiCl₂ (titanium chloride) as the first reaction gas and NH₃ (ammonia) as the second reaction gas. In this case, a gas such as hydrogen gas, argon gas, helium gas, or nitrogen gas may be used as the gas for generating plasma (plasma generation gas); and a gas such as NH₃ gas, N₂H₄ (hydrogen nitride) gas, or amine type gas may be used as the gas for controlling generation of plasma (plasma control gas). Even in this case of performing the reforming process, a uniform film thickness and film property can be attained with respect to the surface of the W.

Further, although the activated gas injector 220 is provided with the sheath pipes 35a, 35b and the gas introduction nozzle 34 along with the cover body 221 having a widely opening lower part according to the above-described embodiments, the sheath pipes 35a, 35b and the gas introduction nozzle 34 may be installed in a box-shaped plasma box, so that an atmosphere including the sheath pipes 35a, 35b and the gas introduction nozzle 34 is separated from an atmosphere being in communication with the process areas P1, P2 of the vacuum chamber 1. In this case, for example, the above-described gas ejection holes 341 are formed below the plasma box.

### Experiment 1

### Wet Etching Rate

An experiment was performed to confirm the uniformity of resistance against wet etching in an in-plane direction of the wafer W in a case of performing a reforming process on a silicon oxide film every deposition cycle (l rotation of the turntable 2) where Ar gas is used together with O₂ gas as the process gas for generating plasma. Because impurities are eliminated from the silicon oxide film by the reforming process, the purity of the silicon oxide wafer is improved and the resistance against wet etching is improved. Thus, this experiment confirmed how much the reforming process was performed by measuring the wet etching rate.

After the silicon oxide film is deposited by the following conditions, a wafer W is steeped in a hydrofluoric acid resolution and then the film thickness of the silicon oxide film is measured, to thereby calculate the wet etching rate. The film thickness of the silicon oxide film was measured in plural areas of the wafer W along a straight line extending from one edge of the wafer W to the other edge of the wafer W so as to correspond to the direction extending from the center of the turntable to the outer circumference of the turntable 2 when the wafer W is placed on the turntable 2. Further, the wet etching rate was also measured with respect to the direction (direction of tangential line of the circumferential edge of the turntable 2) orthogonal to the length direction of the activated gas injector 220.

(DEPOSITION CONDITIONS)

| | | | HIGH |
|---|---|---|---|
| | PROCESS GAS FOR | | FREQUENCY |
| | GENERATING PLASMA AND | | FOR REFORM |
| | GAS FLOW RATE (slm) | | PROCESS |
| COMPARISON | N₂ | | NO |
| EXAMPLE 1 | 5 | | |
| REFERENCE | Ar | O₂ | YES |
| EXAMPLE 1 | 5 | 0 | |
| EMBODIMENT | Ar | O₂ | |
| 1-1 | 5 | 0.1 | |
| EMBODIMENT | Ar | O₂ | |
| 1-2 | 4.5 | 0.5 | |

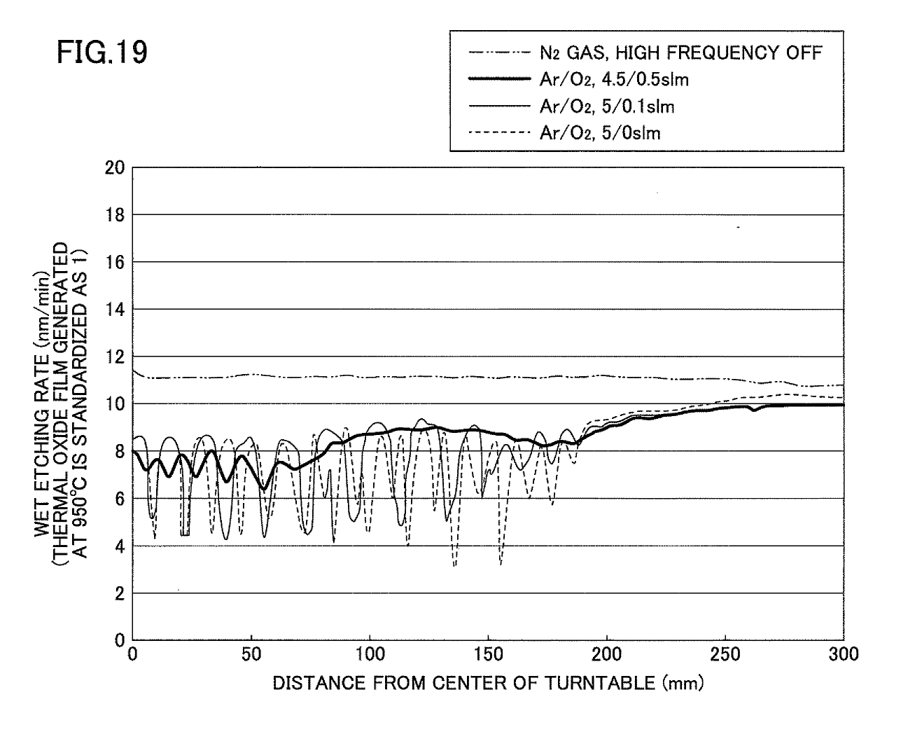

FIG. 19 illustrates the experiment results in a case where the wet etching rate is measured in a direction from the center to the outer circumference of the turntable 2. As it can be understood from FIG. 19, although the wet etching rate is large in a case where the reforming process is not performed, resistance against wet etching is improved by performing the reforming process. In a case where only Ar gas is used as the process gas for generating plasma, the wet etching rate is scattered in a wave-like manner throughout the in-plane direction of the wafer W. In a case where Ar gas is used together with O₂ gas, the wet etching rage is uniform. As a result, it is understood that plasma can be prevented from being locally generated by adding O₂ gas. Further, the more O₂ gas is added, the more the etching rate becomes uniform. The wet etching rate tends to scatter more close to the center of the turntable 2. FIG. 19 illustrates the values obtained in a case where a thermal oxide film's wet etching rate is standardized as 1 at a temperature of 950° C.

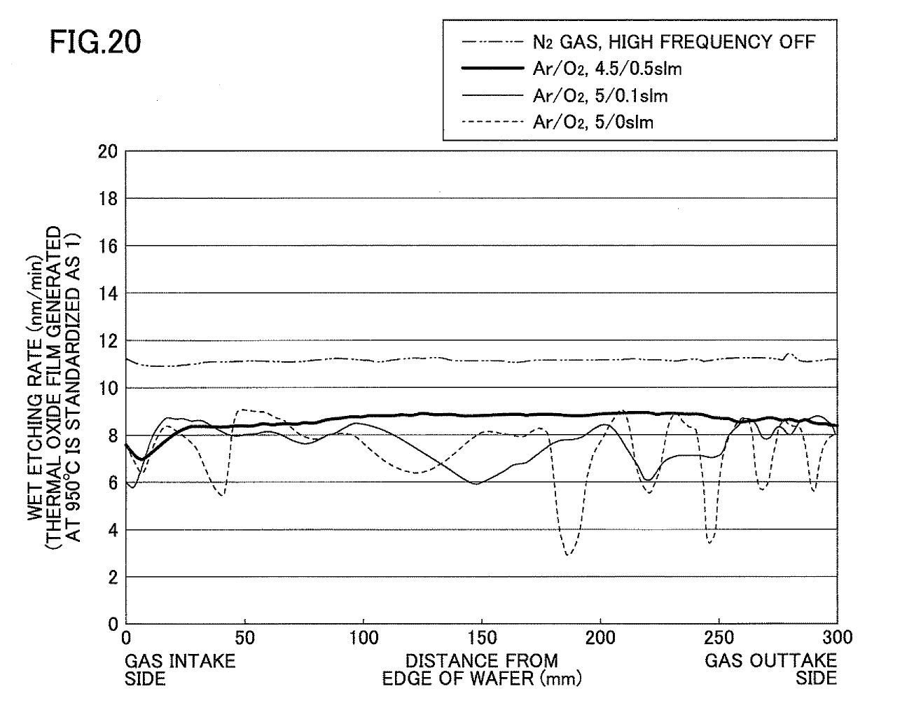

FIG. 20 illustrates results of measuring the wet etching rate in a direction orthogonal to the longitudinal direction of the activated gas injector 220 according to an embodiment of the present invention. It can be understood from this drawing that the same results can be obtained as the above-described experiment results. Further, it can be understood from FIG. 20 that the wet etching rate tends to scatter more at a downstream side than at an upstream side of an upper surface of the wafer W.

### Experiment 2

### Wet Etching Rate

Next, in a similar manner as Experiment 1, an experiment was performed to confirm the uniformity of deposition rate in an in-plane direction of the wafer W in a case where Ar gas is used together with O₂ gas as the process gas for generating plasma. That is, because impurities are eliminated from the silicon oxide film by the reforming process and the silicon oxide film shrinks, this experiment confirmed the uniformity of the reforming process by measuring the deposition rate. The experiment calculates the film deposition rate by measuring the film thickness from the center to the outer circumference of the turntable 2.

(EXPERIMENT CONDITIONS)

| | | | HIGH |
|---|---|---|---|
| | PROCESS GAS FOR | | FREQUENCY |
| | GENERATING PLASMA AND | | FOR REFORM |
| | GAS FLOW RATE (slm) | | PROCESS |
| REFERENCE | Ar | O₂ | YES |
| EXAMPLE 2 | 5 | 0 | |
| EMBODIMENT | Ar | O₂ | |
| 2-1 | 5 | 0.1 | |
| EMBODIMENT | Ar | O₂ | |
| 2-2 | 4.5 | 0.5 | |

In the experiment, diisopropyl amine silane gas having less vapor pressure than the above-described BTBAS gas, having less molecules and having organic material in the molecules being easily datable from silicon atoms, is used as the first reaction gas. Further, the O₃ gas used as the second reaction gas is applied having a density of 300 g/Nm3 and a flow rate of 10 slm (flow rate as O₂ gas).

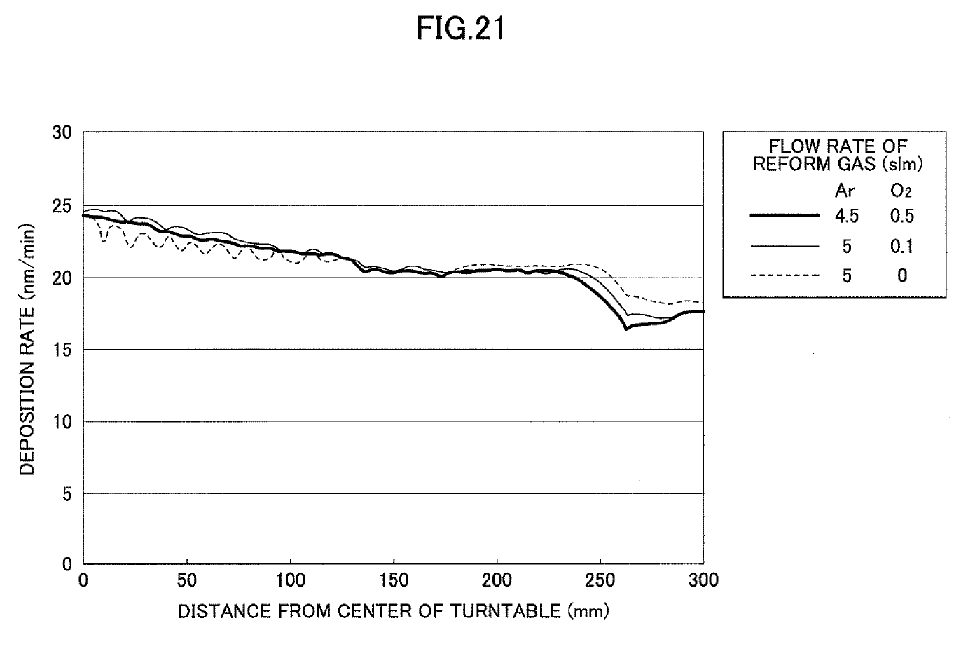

As a result of the experiment, the uniformity of the film deposition rate also improves in the in-plane direction of the wafer W by using Ar gas together with O₂ gas as the process gas for generating plasma as illustrated in FIG. 21. Although there is a difference of film deposition rate in the diameter direction (left-right direction in FIG. 21) of the wafer W, the film deposition rate in the in-plane direction can be matched by adjusting the tilt in the longitudinal direction of the activated gas injector 220 with use of the inclination adjustment mechanism 240.

### Experiment 3

### Scattering of Film Deposition Rate

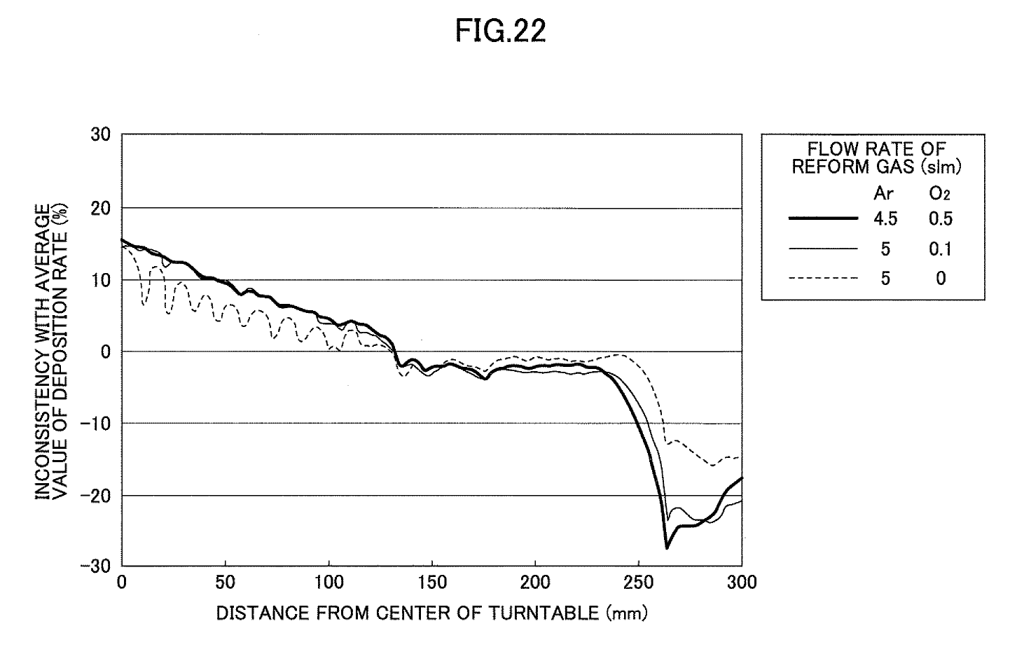

Next, an experiment similar to that of Experiment 2 is performed and then scattering of the film deposition rate is calculated based on the average value of the film deposition rate obtained in the in-plane direction of the wafer W. In this case, the flow rate of the first reaction gas is 275 sccm; the film deposition temperature is 350° C.; the process pressure is 1.07 kPa (8 Torr); and the rotational speed of the turntable 2 is 240 rpm. Other process conditions and the position of measuring the film deposition rate are the same as Experiment 2. As a result, similar to Experiment 2, the scattering of the film deposition rate is reduced as illustrated in FIG. 22 by using Ar gas together with O₂ gas as the process gas for generating plasma.

### Experiment 4

### Shrinkage Amount

In Experiment 4, after film deposition of the silicon oxide film, an experiment was performed to confirm the changes of the shrinkage of the silicon oxide film by using Ar gas added with O₂ gas in a reforming process where the silicon oxide film is annealed at 850° C. under a nitrogen environment. The film deposition conditions are the same as the Experiment 2 except for those indicated.

(DEPOSITION CONDITIONS)

| | | | HIGH |
|---|---|---|---|
| | PROCESS GAS FOR | | FREQUENCY |
| | GENERATING PLASMA AND | | FOR REFORM |
| | GAS FLOW RATE (slm) | | PROCESS |
| COMPARISON | N₂ | | NO |
| EXAMPLE 4 | 5 | | |
| REFERENCE | Ar | O₂ | YES |
| EXAMPLE 4 | 5 | 0 | |
| EMBODIMENT | Ar | O₂ | |
| 4-1 | 5 | 0.1 | |
| EMBODIMENT | Ar | O₂ | |
| 4-2 | 4.5 | 0.5 | |

In the comparison example 4, BTBAS gas is used as the first reaction gas. In other experiments diisopropyl amine silane gas is used as the first reaction gas.

As a result, by performing the reforming process, the amount of shrinkage of the silicon oxide film is reduced at the time of a subsequent annealing process. Accordingly, it can be understood that the silicon oxide film has become denser by the reforming process.

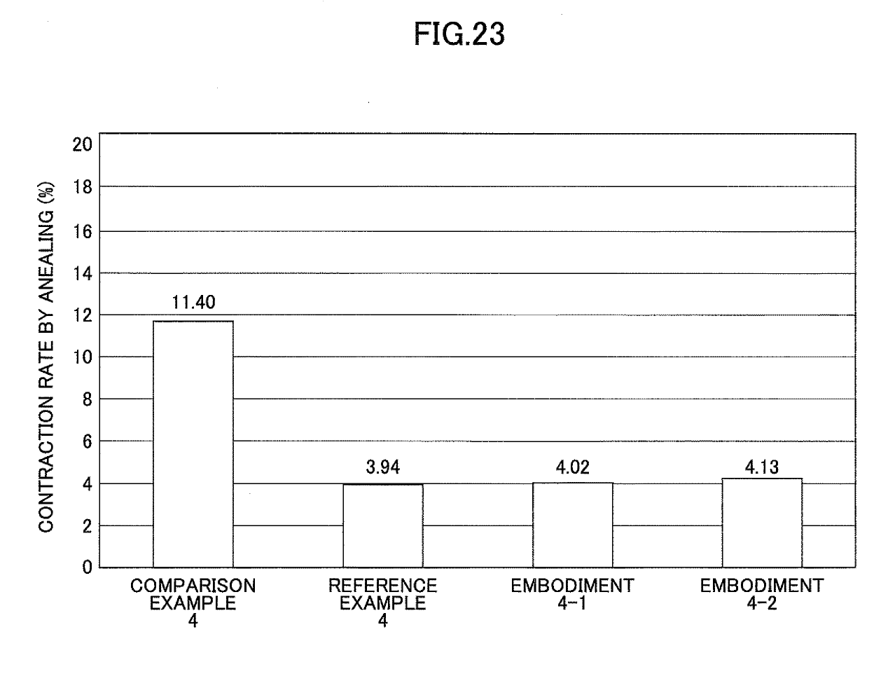

In the case, depending on whether O₂ gas is added to Ar gas, the amount of shrinkage hardly changes. Therefore, it is understood that O₂ gas adversely affects the reforming process. Further, the film thickness was measured at 49 points of the entire surface of the silicon oxide wafer subjected to the reforming process at every film deposition cycle along with calculating the average of the film deposition speed. As a result, it is understood that there is no significant difference in the film deposition rate due to addition of O₂ gas. In FIG. 23, the shrinkage amount of the silicon oxide film is calculated in a case of assuming that the film thickness before the annealing process is 1.

Although not illustrated in the drawings, a transparent window made of quartz is provided in the side wall of the vacuum chamber 1. In observing the radiation state of plasma through the transparent cover body 221 made of quartz, it is understood that the radiation state of plasma is more stable when using Ar gas together with O₂ gas as the process gas for generating plasma compared to using only Ar gas as the process gas for generating plasma.

While the present invention has been described in reference to the foregoing embodiments, the present invention is not limited to the disclosed embodiments, but may be modified or altered within the scope of the accompanying claims.

What is claimed is:

1. A film deposition apparatus for forming a thin film of superposed layers of a reaction product by placing a substrate on a substrate receiving area of a table inside a vacuum chamber, supplying at least two types of reaction gases alternately to the substrate, and performing a plurality of cycles of the supplying, the film deposition apparatus comprising:
a first reaction gas supplying part configured to supply a first reaction gas to the substrate;
a second reaction gas supplying part configured to supply a second reaction gas to the substrate;
an activated gas injector configured to perform a reforming process on the reaction product on the substrate by activating a process gas including a discharge gas and an addition gas having greater electron affinity than the discharge gas and generating plasma in a portion of the substrate receiving area between an inner edge toward a center of the table and an outer edge toward an outer circumference of the table; and
a rotation mechanism configured to relatively rotate the first reaction gas supplying part, the second reaction gas supplying part, the activated gas injector, and the table with each other;
wherein the first reaction gas supplying part, the second reaction gas supplying part, and the activated gas injector are arranged so that the substrate is positioned in this order during the relative rotation.

2. The film deposition apparatus as claimed in claim 1, wherein the activated gas injector includes
a pair of parallel electrodes extending from the inner edge of the substrate receiving area to the outer edge of the substrate receiving area, and
a gas supplying portion configured to supply the process gas between the parallel electrodes.

3. The film deposition apparatus as claimed in claim 2, wherein the activated gas injector includes
a cover body covering the parallel electrodes and the gas supplying portion and having an opening at a bottom portion thereof, and
a gas flow control part extending from lower sides of the cover body in a longitudinal direction and being outwardly bent in a flange-like shape.

4. The film deposition apparatus as claimed in claim 1, wherein the discharge gas includes a gas selected from an argon gas, a helium gas, an ammonia gas, a hydrogen gas, a neon gas, a krypton gas, a xenon gas, and a nitrogen gas, wherein the addition gas includes a gas selected from an oxygen gas, an ozone gas, a hydrogen gas, and an H₂O gas.

5. A film deposition method for forming a thin film of superposed layers of a reaction product by placing a substrate on a substrate receiving area of a table inside a vacuum chamber, supplying at least two types of reaction gases alternately to the substrate, and performing a plurality of cycles of the supplying, the film deposition method comprising the steps of:
placing the substrate in the substrate receiving area on the table;
supplying a first reaction gas to an upper surface of the substrate from a first reaction gas supplying part;
supplying a second reaction gas to the upper surface of the substrate from a second reaction gas supplying part; and
performing a reforming process on the reaction product on the substrate by activating a process gas including a discharge gas and an addition gas having greater electron affinity than the discharge gas and generating plasma in a portion of the substrate receiving area between an inner edge toward a center of the table and an outer edge toward an outer circumference of the table;
wherein the supplying step of the first reaction gas, the supplying step of the second reaction gas, and the performing step of the reforming process are executed a plurality of times in this order by relatively rotating the first reaction gas supplying part, the second reaction gas supplying part, the activated gas injector, and the table with each other.

6. A computer-readable storage medium storing a computer program for use in a film deposition apparatus for forming a thin film of superposed layers of a reaction product by placing a substrate on a substrate receiving area of a table inside a vacuum chamber, supplying at least two types of reaction gases alternately to the substrate, and performing a plurality of cycles of the supplying, the computer program comprising:
instruction steps for causing the film deposition apparatus to execute the film deposition method as claimed in claim 5.
